(19) United States
(12) Patent Application Publication
(10) Pub. No.: US 2025/0212605 A1
(43) Pub. Date: Jun. 26, 2025

(54) DISPLAY DEVICE AND METHOD FOR MANUFACTURING THE SAME

(71) Applicant: Samsung Display Co., LTD., Yongin-si (KR)

(72) Inventors: Jong Hwan CHA, Yongin-si (KR); Yun Sik JOO, Yongin-si (KR); Tetsuhiro TANAKA, Yongin-si (KR); Hong Joon MOON, Yongin-si (KR); Seok Je SEONG, Yongin-si (KR); June Whan CHOI, Yongin-si (KR)

(73) Assignee: Samsung Display Co., LTD., Yongin-si (KR)

(21) Appl. No.: 18/781,046

(22) Filed: Jul. 23, 2024

(30) Foreign Application Priority Data
Dec. 21, 2023 (KR) 10-2023-0188785

(51) Int. Cl. H10K 59/121; H10K 59/12

(52) U.S. Cl. CPC H10K 59/1213; H10K 59/1201

(57) ABSTRACT

A display device according to an embodiment includes a substrate, a first bottom electrode disposed on the substrate and having a first end, a first insulating layer disposed on the first bottom electrode, a second bottom electrode disposed on the first insulating layer and overlapping the first bottom electrode in a plan view, a second insulating layer disposed on the second bottom electrode, and a transistor including an active layer disposed on the second insulating layer, the transistor further including a gate electrode overlapping the active layer, wherein the second bottom electrode overlaps the active layer in a plan view and has a second end adjacent to the first end, and the first end and the second end do not overlap in a plan view.

### CROSS-REFERENCE TO RELATED APPLICATIONS

This application claims priority under 35 U.S.C. § 119 from Korean Patent Application No. 10-2023-0188785 filed on Dec. 21, 2023 in the Korean Intellectual Property Office, the entire contents of which are incorporated herein by reference.

### BACKGROUND

### 1. Technical Field

The disclosure relates to a display device and a method for manufacturing the same.

### 2. Description of the Related Art

With the advance of information-oriented society, more and more demands are placed on display devices for displaying images in various ways. Along with this trend, various types of display devices including a light emitting display devices are being developed. The display devices may include a transistor to control the operation of a pixel.

### SUMMARY

Aspects of the disclosure provide a display device capable of improving an operating characteristic of a transistor and a method for manufacturing the same.

However, aspects of the disclosure are not restricted to the one set forth herein. The above and other aspects of the disclosure will become more apparent to one of ordinary skill in the art to which the disclosure pertains by referencing the detailed description of the disclosure given below.

According to an aspect of the disclosure, there may be provided a display device that may include a substrate, a first bottom electrode disposed on the substrate and having a first end, a first insulating layer disposed on the first bottom electrode, a second bottom electrode disposed on the first insulating layer, the second bottom electrode overlapping the first bottom electrode in a plan view, a second insulating layer disposed on the second bottom electrode, and a transistor including an active layer disposed on the second insulating layer, the transistor may include a gate electrode overlapping the active layer in a plan view. The second bottom electrode may overlap the active layer in a plan view and may have a second end adjacent to the first end, and the first end and the second end may not overlap in a plan view.

In an embodiment, the first end and the second end may be spaced apart from each other by a distance of at least about 0.6 μm in a plan view.

In an embodiment, a part of the second bottom electrode may overlap the first end, and the second end may extend from the part of the second bottom electrode to an outside of the first end.

In an embodiment, a part of the first bottom electrode may overlap the second end, and the first end may extend from the part of the first bottom electrode to an outside of the second end.

In an embodiment, the first bottom electrode may include a first metal layer containing aluminum (Al) and a second metal layer disposed on the first metal layer, and the second metal layer may contain titanium (Ti).

In an embodiment, the first bottom electrode may further include a third metal layer disposed below the first metal layer, and the third metal layer may contain titanium (Ti).

In an embodiment, the second metal layer and the third metal layer may completely cover a top surface and a bottom surface respectively of the first metal layer.

In an embodiment, the second bottom electrode may include a first metal layer containing aluminum (Al) and a second metal layer disposed on the first metal layer, the second metal layer may contain titanium (Ti).

In an embodiment, the second bottom electrode may further include a third metal layer disposed below the first metal layer, and the third metal layer may contain titanium (Ti).

In an embodiment, the second metal layer and the third metal layer may completely cover a top surface and a bottom surface respectively of the first metal layer.

In an embodiment, the second insulating layer may include a first layer containing silicon nitride and a second layer disposed on the first layer, and the second layer may contain silicon oxide or silicon oxynitride.

In an embodiment, a thickness of the first layer may be greater than a thickness of the second layer.

In an embodiment, the first layer may have a thickness in a range of about 1000 Å to about 2000 Å.

In an embodiment, the active layer may contain an oxide semiconductor.

In an embodiment, the display device may further include a gate insulating layer disposed between the active layer and the gate electrode, the gate insulating layer may cover a portion of the active layer, include a portion overlapping the gate electrode, and expose another portion of the active layer.

In an embodiment, the transistor may further include a source electrode disposed on a third insulating layer, the third insulating layer may be disposed on the gate electrode, and the second bottom electrode may be electrically connected to the source electrode.

In an embodiment, the third insulating layer may include a first layer containing silicon oxide or silicon oxynitride and a second layer disposed on the first layer, and the second layer may contain silicon nitride.

In an embodiment, the display device may further include a light emitting element electrically connected to the transistor.

According to an aspect of the disclosure, there may be provided a method for manufacturing a display device, including forming a first bottom electrode on a substrate, the first bottom electrode may have a first end, forming a first insulating layer on the first bottom electrode, forming a second bottom electrode on the first insulating layer, the second bottom electrode may overlap the first bottom electrode in a plan view, and the second bottom electrode may have a second end adjacent to the first end, forming a second insulating layer on the second bottom electrode, and forming a transistor on the second insulating layer, the transistor may include an active layer that overlaps the second bottom electrode in a plan view, wherein the first end and the second end may not overlap in a plan view.

In an embodiment, the first end and the second end may be spaced apart from each other by a distance of at least about 0.6 μm in a plan view.

According to the display device and the method for manufacturing the same according to embodiments, it may be possible to prevent or block hydrogen from being introduced into an active layer of the transistor. Accordingly, the operating characteristic of the transistor may be improved, and the image quality of the display device may be improved.

However, effects according to the embodiments of the disclosure are not limited to those exemplified above and various other effects are incorporated herein.

### BRIEF DESCRIPTION OF THE DRAWINGS

The above and other aspects and features of the disclosure will become more apparent by describing in detail embodiments thereof with reference to the attached drawings, in which:

FIG. 1 is a plan view illustrating a display device according to an embodiment;

FIG. 2 is a plan view illustrating a display panel of FIG. 1;

FIG. 3 is a schematic diagram of an equivalent circuit of a pixel according to an embodiment;

FIG. 4 is a schematic cross-sectional view illustrating a display panel according to an embodiment;

FIG. 5 is a schematic cross-sectional view showing area A of FIG. 4 in detail;

FIG. 6 is a schematic cross-sectional view showing area A of FIG. 4 in detail;

FIG. 7 is a schematic cross-sectional view illustrating a display panel according to an embodiment;

FIG. 8 is a schematic cross-sectional view showing area C of FIG. 7 in detail;

FIG. 9 is a schematic cross-sectional view showing area C of FIG. 7 in detail; and

FIGS. 10 to 18 are schematic cross-sectional views illustrating a method for manufacturing a display device according to an embodiment.

### DETAILED DESCRIPTION OF THE EMBODIMENTS

In the following description, for the purposes of explanation, numerous specific details are set forth in order to provide a thorough understanding of various embodiments or implementations of the disclosure. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the disclosure. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals and/or reference characters denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the X-axis, the Y-axis, and the Z-axis are not limited to three axes of a rectangular coordinate system, such as the x, y, and z axes, and may be interpreted in a broader sense. For example, the X-axis, the Y-axis, and the Z-axis may be perpendicular to one another, or may be different directions that are not perpendicular to one another.

For the purposes of this disclosure, “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the inventive concepts. Further, the blocks, units, and/or modules of some embodiments may be physically combined into more complex blocks, units, and/or modules without departing from the scope of the inventive concepts.

Unless otherwise defined or implied herein, all terms (including technical and scientific terms) used herein have the same meaning as commonly understood by those skilled in the art to which this disclosure pertains. It will be further understood that terms, such as those defined in commonly used dictionaries, should be interpreted as having a meaning that is consistent with their meaning in the context of the relevant art and the disclosure, and should not be interpreted in an ideal or excessively formal sense unless clearly so defined herein.

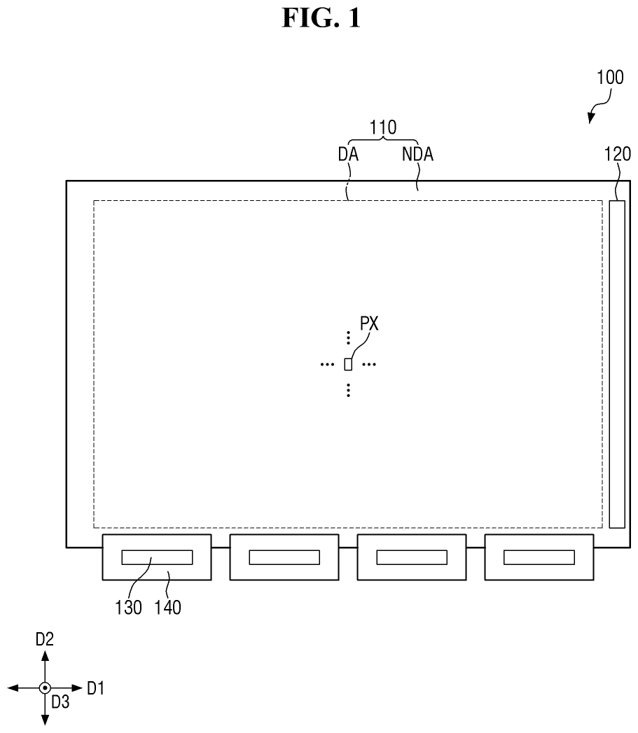

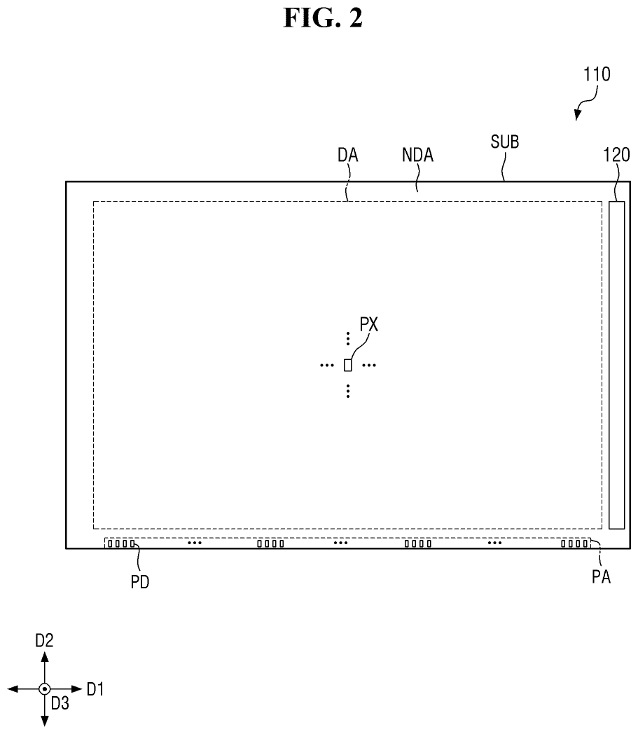

FIG. 1 is a plan view illustrating a display device 100 according to an embodiment. FIG. 2 is a plan view illustrating a display panel 110 of FIG. 1.

Referring to FIGS. 1 and 2, the display device 100 may be a device for displaying a moving image or a still image. The display device 100 may be used as a display screen of various devices, such as a television, a laptop computer, a monitor, a billboard, and an Internet-of-Things (IoT) device, as well as portable electronic devices such as a mobile phone, a smartphone, a tablet personal computer (PC), a smart watch, a watch phone, a mobile communication terminal, an electronic notebook, an electronic book, a portable multimedia player (PMP), a navigation device, and an ultra-mobile PC (UMPC). These may be presented as nothing more than examples, and the display device 100 may be applicable to various other types of electronic devices.

In an embodiment, the display device 100 may be a light emitting display device such as an organic light emitting display including an organic light emitting diode, a quantum dot light emitting display including a quantum dot light emitting layer, an inorganic light emitting display including an inorganic semiconductor, or an ultra-small light emitting display including an ultra-small light emitting diode such as a micro or nano light emitting diode (micro LED or nano LED), but is not limited thereto. For example, the display device 100 may be another type of display device other than a light emitting display device. In the following, embodiments in which the display device 100 may be a light emitting display device (e.g., an organic light emitting display device) will be disclosed.

The display device 100 may include the display panel 110 including pixels PX, and a first driver 120 and a second driver 130 configured to supply driving signals to the pixels PX. The display device 100 may further include additional components. For example, the display device 100 may further include a power supply part for supplying power voltages to the pixels PX, the first driver 120, and the second driver 130, and a timing controller for controlling the operations of the first driver 120 and the second driver 130.

The display panel 110 may include a display area DA and a non-display area NDA. The display area DA may be an area including the pixels PX to display an image. For example, the display area DA may include pixel areas where the pixels PX may be arranged. The non-display area NDA may be an area other than the display area DA, and an image may not be displayed in the non-display area NDA. In an embodiment, the non-display area NDA may be positioned around the display area DA and may surround the display area DA.

In FIGS. 1 and 2, a first direction D1, a second direction D2, and a third direction D3 may be defined. In an embodiment, the first direction D1 may be the horizontal direction of the display panel 110, and the second direction D2 may be the vertical direction of the display panel 110. The third direction D3 may be a thickness direction of the display panel 110.

In an embodiment, the display panel 110 may have a rectangular shape in a plan view. Although FIGS. 1 and 2 illustrate the display panel 110 with a horizontal length longer than a vertical length, the shape of the display panel 110 is not limited thereto. For example, the display panel 110 may have a shape with a vertical length longer than a horizontal length, a square shape, or the like. The display panel 110 may include an angled corner or a rounded corner.

The planar shape of the display panel 110 is not limited to the illustrated quadrilateral shape, and it may be applied in other shapes. For example, the display panel 110 may have a non-quadrilateral polygonal shape, a circular shape, an elliptical shape, an atypical shape, or another shape in a plan view.

In an embodiment, the display panel 110 may be substantially flat on the plane defined by the first direction D1 and the second direction D2, and may have a uniform thickness in the third direction D3. In another example, the display panel 110 may be provided in a three-dimensional shape having a curved surface or the like.

The display panel 110 may be provided as a rigid panel so as not to be substantially transformed, or as a flexible panel that can be transformed to be at least partially folded, bent, or rolled. The display panel 110 may be provided to the display device 100 without bending, or may be provided to the display device 100 while being partially bent.

The display panel 110 may include a substrate SUB and the pixels PX disposed on the substrate SUB. The pixels PX may be disposed in the display area DA on the substrate SUB.

The substrate SUB, which may be a base member for manufacturing or providing the display panel 110, may form the base surface of the display panel 110. The substrate SUB may include the display area DA and the non-display area NDA around the display area DA.

The display area DA may have various shapes depending on embodiments. For example, the display area DA may have a quadrilateral shape, a non-quadrilateral polygonal shape, a circular shape, an elliptical shape, an atypical shape, or another shape. In an embodiment, the display area DA may have a shape conforming to the shape of the display panel 110.

The pixels PX may be provided and/or arranged in the display area DA. For example, the display area DA may include multiple pixel areas in which the respective pixels PX may be disposed.

In an embodiment, the display device 100 may be a light emitting display device, and each pixel PX may include a light emitting element located in each emission area and a pixel circuit electrically connected to the light emitting element. In describing embodiments, the term “connect” may include electrical connection and/or physical connection. Each pixel circuit may include transistors (e.g., transistors including a driving transistor that generates a driving current corresponding to a data signal, and at least one switching transistor) and at least one capacitor (e.g., a capacitor including a storage capacitor).

The non-display area NDA may include a pad area PA where pads PD may be disposed. In an embodiment, the non-display area NDA may further include a driving circuit area located on at least one side of the display area DA. At least one driver, the pads PD, and/or wires may be disposed in the non-display area NDA.

At least one driver for driving the pixels PX, or a part of the driver may be disposed in the driving circuit area. For example, circuit elements constituting the first driver 120 (e.g., driver transistors and driver capacitors constituting the stage circuits of the first driver 120) may be disposed in the driving circuit area on the substrate SUB. In an embodiment, the circuit elements of the first driver 120 may be formed in the display panel 110 together with the pixels PX. In an embodiment, the driving transistors provided in the first driver 120 may be transistors having a type and/or a structure that may be substantially the same as or similar to those of the transistors provided in the pixels PX, and may be formed simultaneously with the transistors of the pixels PX.

The pads PD may be disposed in the pad area PA. At least one circuit board 140 may be disposed and/or bonded on the pad area PA. In an embodiment, multiple circuit boards 140 electrically connected to different pads PD may be disposed on the pad area PA. The pads PD may include signal pads and power pads for transmitting driving signals and power voltages required for driving the pixels PX and/or the first driver 120 into the display panel 110.

The first driver 120 and the second driver 130 may generate driving signals for controlling operation timing, luminance, and the like of the pixels PX, and may supply the generated driving signals to the pixels PX. For example, the first driver 120 may be a gate driver including a scan driver, and may be electrically connected to the pixels PX through respective gate lines. The first driver 120 may supply respective gate signals (e.g., control signals for controlling the driving timing of the pixels PX, including scan signals and/or emission control signals) to the pixels PX. The second driver 130 may be a data driver including source driving circuits, and may be electrically connected to the pixels PX through respective data lines. The second driver 130 may supply respective data signals to the pixels PX.

In an embodiment, at least one first driver of the first driver 120 or the second driver 130, or a part of the at least one first driver may be embedded in the display panel 110. For example, the first driver 120 or a part of the first driver 120 may be disposed and/or formed in the non-display area NDA and disposed on the substrate SUB of the display panel 110.

Although FIG. 1 illustrates that the first driver 120 may be formed on a side of the display area DA (e.g., in the non-display area NDA on the right side of the display area DA), but the embodiments are not limited thereto. For example, the first driver 120 may be positioned only on another side (e.g., the non-display area NDA on the left side of the display area DA) of the display area DA, or may be positioned on both sides (e.g., the non-display area NDA on the left side and right side of the display area DA) of the display area DA. In other example, a part of the first driver 120 may be portioned in the non-display area NDA, and another part of the first driver 120 may be positioned in a non-emission area (e.g., an area between emission areas of the pixels PX) inside the display area DA.

In an embodiment, another driver of the first driver 120 and the second driver 130 or a part of another driver may be disposed or formed outside the display panel 110 to be electrically connected to the display panel 110. For example, the second driver 130 may be implemented as a multiple number of integrated circuit chips, which may be disposed on the circuit boards 140 electrically connected to the pixels PX of the display panel 110. The second driver 130 may be implemented as at least one integrated circuit chip and mounted on the non-display area NDA of the display panel 110.

The circuit board 140 may be electrically connected to the display panel 110 through the pads PD. In an embodiment, the circuit board 140 may be a flexible film such as a flexible printed circuit board (FPCB), a printed circuit board (PCB), or a chip on film (COF), but is not limited thereto. In an embodiment, the circuit board 140 may be electrically connected to the timing controller and/or the power supply part through another circuit board, connector, or the like.

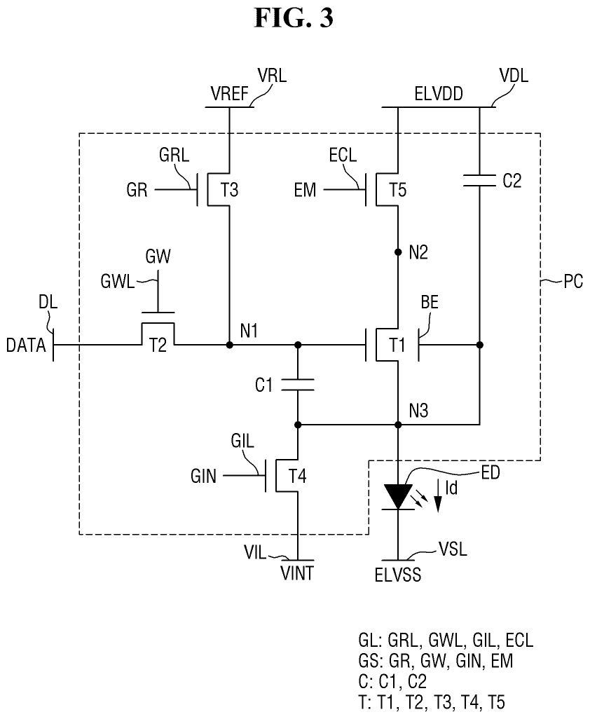

FIG. 3 is a schematic diagram of an equivalent circuit of the pixel PX according to an embodiment. For example, FIG. 3 shows the pixel PX of the light emitting display device including a light emitting element ED. In addition to the embodiment of FIG. 3, the type and/or structure of the pixel PX that may be included in the display device 100 may be variously changed depending on embodiments.

Referring to FIG. 3 in addition to FIGS. 1 and 2, the pixel PX may include the light emitting element ED, and a pixel circuit PC electrically connected to the light emitting element ED. The light emitting element ED may be a light source of the pixel PX, and it may be, for example, an organic light emitting diode, but is not limited thereto. The pixel circuit PC may control the emission time point and the luminance of the light emitting element ED.

The pixel circuit PC may include transistors T and at least one capacitor C. For example, the pixel circuit PC may include first to fifth transistors T1 to T5, and first and second capacitors C1 and C2. Although FIG. 3 shows an embodiment in which all the transistors T may be N-type transistors, the types of the transistors T are not limited thereto. For example, at least one transistor T may be formed of a P-type transistor.

The pixel circuit PC may supply a driving current Id to the light emitting element ED in response to the driving signals supplied from the first driver 120 and the second driver 130. For example, the pixel circuit PC may supply the driving current Id to the light emitting element ED in response to respective gate signals GS supplied from the first driver 120 through respective gate lines GL and a data signal DATA supplied from the second driver 130 through a data line DL.

The first transistor T1 may be a driving transistor of the pixel PX whose magnitude of drain-source current (e.g., the driving current Id) may be determined depending on the gate-source voltage. The second, third, fourth, and fifth transistors T2, T3, T4, and T5 may be switching transistors that may be turned on or off depending on respective gate-source voltages. Depending on the type (e.g., P-type or N-type) and/or operating conditions of each of the first to fifth transistors T1 to T5, a first electrode of each of the first to fifth transistors T1 to T5 may be a drain electrode (or a drain region), or a source electrode (or a source region), and a second electrode thereof may be an electrode different from the first electrode. For example, in case that the first electrode is a drain electrode, the second electrode may be a source electrode.

The pixel PX may be electrically connected to a first gate line GWL that transmits a first gate signal GW (e.g., a scan signal), a second gate line GIL that transmits a second gate signal GIN, a third gate line GRL that transmits a third gate signal GR, an emission control line ECL that transmits an emission control signal EM, and the data line DL that transmits the data signal DATA. Further, the pixel PX may be electrically connected to a first power line VDL that transmits a first pixel voltage ELVDD (also referred to as “first pixel power voltage”), and a second power line VSL that transmits a second pixel voltage ELVSS (also referred to as “second pixel power voltage”). In an embodiment, the pixel PX may be further electrically connected to an initialization power line VIL that transmits an initialization voltage VINT (also referred to as “third pixel power voltage”), and a reference power line VRL that transmits a reference voltage VREF (also referred to as “fourth pixel power voltage”).

In an embodiment, the first to fifth transistors T1 to T5 may be located in each pixel area, and may be oxide transistors (also referred to as “oxide semiconductor transistors”) including an oxide semiconductor (e.g., an oxide semiconductor material). By way of example, an active layer of each of the first to fifth transistors T1 to T5 may include the oxide semiconductor. However, the embodiments are not limited thereto. For example, at least one transistor T may be formed of a semiconductor material (e.g., amorphous silicon or polysilicon) other than an oxide semiconductor.

The oxide semiconductor may have high carrier mobility and a low leakage current, so that a considerable voltage drop may not occur even if the driving time of the oxide transistor increases. For example, the pixel PX including an oxide transistor may be driven at a low frequency because the change in the luminance and/or the color of an image due to a voltage drop may not be significant even in case that it is driven at a low frequency. In case that the first to fifth transistors T1 to T5 are formed of oxide transistors, the leakage current of the pixel PX may be reduced or prevented and the power consumption may be reduced.

The oxide semiconductor may be sensitive to light, so that the amount of current or the like may be changed due to external light. In an embodiment, a light blocking pattern or a light blocking electrode (e.g., a bottom electrode or a back-gate electrode) may be disposed under the active layer included in at least one transistor T to block external light. Accordingly, the operating characteristics of the transistor T may be stabilized.

The first transistor T1 may include a gate electrode electrically connected to a first node N1, a first electrode (e.g., a drain electrode) electrically connected to a second node N2, and a second electrode (e.g., a source electrode) electrically connected to a third node N3. The first electrode of the first transistor T1 may be electrically connected to the first power line VDL via the fifth transistor T5, and the second electrode thereof may be electrically connected to the light emitting element ED. The first transistor T1 may control the magnitude (e.g., current amount) of the driving current Id flowing to the light emitting element ED to correspond to the data signal DATA transmitted to the first node N1.

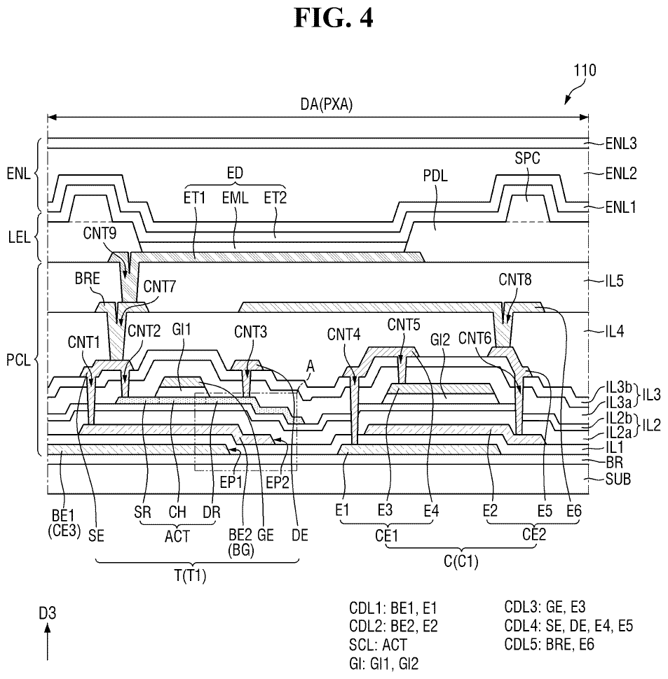

In an embodiment, the first transistor T1 may further include a bottom electrode BE (e.g., a second bottom electrode BE2 in FIG. 4) electrically connected to the third node N3. In case that the first transistor T1 may be formed of a transistor having a double gate structure (e.g., a double gate transistor having a source-sync structure) by connecting the bottom electrode BE of the first transistor T1 to the third node N3, the operating characteristics of the first transistor T1 may be improved.

The second transistor T2 may include a gate electrode electrically connected to the first gate line GWL, a first electrode electrically connected to the data line DL, and a second electrode electrically connected to the first node N1. The second transistor T2 may be turned on by the first gate signal GW (e.g., the first gate signal GW of the gate-on voltage) transmitted to the first gate line GWL to connect the data line DL and the first node N1. Accordingly, the data signal DATA transmitted through the data line DL may be sent to the first node N1.

The third transistor T3 may include a gate electrode electrically connected to the third gate line GRL, a first electrode electrically connected to the reference power line VRL, and a second electrode electrically connected to the first node N1. The third transistor T3 may be turned on by the third gate signal GR transmitted through the third gate line GRL and transmit the reference voltage VREF transmitted to the reference power line VRL to the first node N1.

The fourth transistor T4 may include a gate electrode electrically connected to the second gate line GIL, a first electrode electrically connected to the third node N3, and a second electrode electrically connected to the initialization power line VIL. The fourth transistor T4 may be turned on by the second gate signal GIN transmitted through the second gate line GIL and transmit the initialization voltage VINT transmitted to the initialization power line VIL to the third node N3.

The fifth transistor T5 may include a gate electrode electrically connected to the emission control line ECL, a first electrode electrically connected to the first power line VDL, and a second electrode electrically connected to the second node (or the first electrode of the first transistor T1). The fifth transistor T5 may be turned on by the emission control signal EM (e.g., the emission control signal EM of the gate-on voltage) transmitted to the emission control line ECL to control the emission time point of the pixel PX.

Each of the second to fifth transistors T2 to T5 may or may not include the bottom electrode. In an embodiment, at least one switching transistor among the second to fifth transistors T2 to T5 may include the bottom electrode, and the bottom electrode of the at least one switching transistor may be electrically connected to the gate electrode of the corresponding switching transistor. In case that the bottom electrode of the switching transistor is electrically connected to the gate electrode, it may be possible to improve the off characteristics and the switching speed of the switching transistor, secure an additional voltage tolerance range, lower a leakage current, and improve voltage stability. For example, since a switching transistor formed of an oxide transistor with a short channel length may be formed in a double gate structure such as a gate-sync structure or the like, the operating characteristics of the switching transistor may be improved.

The first capacitor C1 may be electrically connected between the first node N1 and the third node N3. The first capacitor C1 may be a storage capacitor of the pixel PX, and may store therein a threshold voltage of the first transistor T1 and a voltage corresponding to the data signal DATA (e.g., a data voltage).

The second capacitor C2 may be electrically connected between the first power line VDL and the third node N3. In an embodiment, the capacitance of the second capacitor C2 may be less than that of the first capacitor C1.

The light emitting element ED may be electrically connected between the third node N3 and the second power line VSL. For example, the light emitting element ED may include a first electrode (e.g., an anode electrode) electrically connected to the third node N3, a second electrode (e.g., a cathode electrode) facing the first electrode and electrically connected to the second power line VSL, and a light emitting layer disposed between the first electrode and the second electrode. In an embodiment, the first electrode of the light emitting element ED may be an individual electrode individually provided in each pixel PX, and the second electrode of the light emitting element ED may be a common electrode shared by the pixels PX. The light emitting element ED may emit light with a luminance corresponding to the driving current Id during a time period in which the driving current Id may be supplied from the pixel circuit PC.

FIG. 4 is a schematic cross-sectional view illustrating the display panel 110 according to an embodiment. For example, FIG. 4 shows a part of the display area DA of the display panel 110. FIG. 4 illustrates a light emitting display panel including the light emitting element ED (e.g., an organic light emitting diode) as an example of the display panel 110 to which embodiments may be applied.

Referring to FIG. 4 in addition to FIGS. 1 to 3, the display panel 110 may include the substrate SUB (or base layer), a panel circuit layer PCL (or thin film transistor layer), a light emitting element layer LEL, and an encapsulation layer ENL. The panel circuit layer PCL, the light emitting element layer LEL, and the encapsulation layer ENL may be disposed to overlap each other on the substrate SUB. For example, with respect to the display area DA, the panel circuit layer PCL, the light emitting element layer LEL, and the encapsulation layer ENL may be sequentially disposed on the substrate SUB in the third direction D3. The positions of the panel circuit layer PCL, the light emitting element layer LEL, and/or encapsulation layer ENL may change depending on embodiments.

In an embodiment, the display panel 110 may further include additional elements provided above and/or under the encapsulation layer ENL. For example, the display panel 110 may further include at least one of a sensor layer (e.g., a touch sensor layer), an optical layer (for example, a color filter layer and/or a wavelength conversion layer), or a passivation layer (e.g., a passivation film, an insulating layer, an upper substrate, and/or a window). Each of the sensor layer, the optical layer, and/or the passivation layer may be provided above the encapsulation layer ENL or may be provided between the light emitting element layer LEL and the encapsulation layer ENL.

The substrate SUB, which may be a base member for forming the display panel 110, may be a rigid or flexible substrate (or film). In an embodiment, the substrate SUB may be a substrate including an insulating material such as glass or the like and having rigid characteristics, and may not be bent. In another example, the substrate SUB may be a flexible substrate that includes polyimide or another insulating material and may be transformed to be bent, folded, or rolled, and may or may not be bent. The type and/or material of the substrate SUB may change depending on embodiments.

In an embodiment, the display panel 110 may optionally further include a barrier layer BR disposed between the substrate SUB and the panel circuit layer PCL. For example, the barrier layer BR may be disposed on the substrate SUB and the panel circuit layer PCL may be disposed on the barrier layer BR, or the panel circuit layer PCL may be disposed (e.g., directly disposed) on the substrate SUB without the barrier layer BR.

The barrier layer BR may include at least one inorganic insulating layer containing an inorganic insulating material (e.g., silicon nitride, silicon oxide, silicon oxynitride, titanium oxide, aluminum oxide, or another inorganic insulating material). The barrier layer BR may protect the pixels PX from moisture permeating through the substrate SUB that may be susceptible to moisture permeation. The material of the barrier layer BR may be variously changed according to embodiments.

The panel circuit layer PCL may be disposed on a surface of the substrate SUB where the barrier layer BR may be provided. The panel circuit layer PCL may include circuit elements including the transistors T and the capacitors C of the pixels PX, and wires (e.g., signal lines and power lines). In an embodiment, the panel circuit layer PCL may further include circuit elements (e.g., driving transistors and/or driving capacitors provided in the first driver 120) of the first driver 120, and/or additional conductive patterns (e.g., bridge patterns).

FIG. 4 shows the transistor T and the capacitor C disposed in any one pixel area PXA, as an example of the circuit elements that may be provided in the panel circuit layer PCL. The transistor T of FIG. 4 may be a driving transistor or a switching transistor provided in the pixel circuit PC of the corresponding pixel PX. For example, the transistor T of FIG. 4 may be the first transistor T1 of FIG. 3. The capacitor C of FIG. 4 may be any one capacitor C provided in the pixel circuit PC of the corresponding pixel PX. For example, the capacitor C of FIG. 4 may be the first capacitor C1 of FIG. 3. In an embodiment, the second capacitor C2 of FIG. 3 may be formed around the first transistor T1. For example, the second capacitor C2 may be formed under the transistor T by the first bottom electrode BE1 and the second bottom electrode BE2.

The panel circuit layer PCL may include conductive layers and a semiconductor layer SCL where circuit elements and wires may be provided. The electrodes constituting the circuit elements (e.g., the transistors T and the capacitors C) of the panel circuit layer PCL, and the conductive patterns (e.g., bridge electrodes BRE and/or wires) electrically connected to the electrodes and/or the wires may be provided in the conductive layers. The active layers ACT of the transistors T provided in the panel circuit layer PCL may be provided in the semiconductor layer SCL.

In an embodiment, the panel circuit layer PCL may include a first conductive layer CDL1 (also referred to as “first lower conductive layer” or “first bottom conductive layer”), a second conductive layer CDL2 (also referred to as “second lower conductive layer” or “second bottom conductive layer”), the semiconductor layer SCL, a third conductive layer CDL3 (also referred to as “gate conductive layer”), and a fourth conductive layer CDL4 (also referred to as “first source-drain conductive layer” or “first data conductive layer”) that may be sequentially disposed on the substrate SUB in the third direction D3. In an embodiment, the panel circuit layer PCL may further include a fifth conductive layer CDL5 (also referred to as “second source-drain conductive layer” or “second data conductive layer”) disposed on the fourth conductive layer CDL4. For example, the first conductive layer CDL1 and the second conductive layer CDL2 may be disposed below the semiconductor layer SCL (e.g., between the substrate SUB and the semiconductor layer SCL), and the third conductive layer CDL3, the fourth conductive layer CDL4, and the fifth conductive layer CDL5 may be disposed above the semiconductor layer SCL (e.g., between the semiconductor layer SCL and the light emitting element layer LEL).

The respective electrodes, conductive patterns, and/or wires provided on the conductive layers of the panel circuit layer PCL may include at least one conductive material. For example, the electrodes, the conductive patterns, and/or the wires provided in each of the first conductive layer CDL1, the second conductive layer CDL2, the third conductive layer CDL3, the fourth conductive layer CDL4, and the fifth conductive layer CDL5 may include at least one of copper (Cu), titanium (Ti), molybdenum (Mo), aluminum (Al), chromium (Cr), gold (Au), silver (Ag), platinum (Pt), palladium (Pd), nickel (Ni), neodymium (Nd), iridium (Ir), tantalum (Ta), tungsten (W), magnesium (Mg), or another metal, an alloy thereof, or another conductive material. In an embodiment, the electrodes, the conductive patterns, and/or the wires disposed on the same conductive layer may be simultaneously formed using the same conductive material.

In an embodiment, each of the electrodes, conductive patterns, and/or wires provided in the conductive layers of the panel circuit layer PCL may have a single-layer or multi-layer structure. For example, the electrodes, the conductive patterns, and/or the wires provided in the first conductive layer CDL1, the second conductive layer CDL2, the third conductive layer CDL3, the fourth conductive layer CDL4, and the fifth conductive layer CDL5 may have a single-layer or multi-layer structure. In an embodiment, the electrodes, the conductive patterns, and/or the wires provided on the same conductive layer may be simultaneously formed using a same material.

The panel circuit layer PCL may further include multiple insulating layers and/or insulating patterns disposed on the substrate SUB. For example, the panel circuit layer PCL may include a first insulating layer IL1, a second insulating layer IL2, a gate insulating layer GI, a third insulating layer IL3, a fourth insulating layer IL4, and a fifth insulating layer IL5 that may be sequentially disposed on the substrate SUB in the third direction D3.

The first insulating layer IL1 may be disposed between the first conductive layer CDL1 and the second conductive layer CDL2, and may cover the first conductive layer CDL1. For example, the first insulating layer IL1 may be disposed on the substrate SUB, and electrodes (e.g., the first bottom electrode BE1, and a first electrode E1 of the capacitor C), wires, and/or conductive patterns provided in the first conductive layer CDL1.

The second insulating layer IL2 may be disposed between the second conductive layer CDL2 and the semiconductor layer SCL, and may cover the second conductive layer CDL2. For example, the second insulating layer IL2 may be disposed on the first insulating layer IL1, and electrodes (e.g., the second bottom electrode BE2, and a second electrode E2 of the capacitor C), wires, and/or conductive patterns provided in the second conductive layer CDL2.

In an embodiment, the second insulating layer IL2 may be an insulating layer of double or more layers. For example, the second insulating layer IL2 may include a first layer IL2a disposed on the second conductive layer CDL2, and a second layer IL2b disposed on the first layer IL2a.

The gate insulating layer GI may be disposed on the second insulating layer IL2 and the semiconductor layer SCL. For example, the gate insulating layer GI may be disposed between the second insulating layer IL2 and the semiconductor layer SCL and the third conductive layer CDL3. The gate insulating layer GI may cover a part of each of the second insulating layer IL2 and the semiconductor layer SCL.

The third insulating layer IL3 may be disposed on the second insulating layer IL2. For example, the third insulating layer IL3 may be disposed between the third conductive layer CDL3 and the fourth conductive layer CDL4. The third insulating layer IL3 may cover the semiconductor layer SCL, the gate insulating layer GI, and the third conductive layer CDL3. For example, the third insulating layer IL3 may be disposed on the active layers ACT provided in the semiconductor layer SCL, the insulating patterns (e.g., a first gate insulating layer GI1 and a second gate insulating layer GI2 that may be integrated with each other or separated from each other) provided in the gate insulating layer GI, and the electrodes (e.g., the gate electrode GE of the transistor T, and the third electrode E3 of the capacitor C), the wires, and/or the conductive patterns provided in the third conductive layer CDL3.

In an embodiment, the third insulating layer IL3 may be an insulating layer of double or more layers. For example, the third insulating layer IL3 may include a first layer IL3a disposed on the third conductive layer CDL3, and a second layer IL3b disposed on the first layer IL3a.

The fourth insulating layer IL4 may be disposed between the fourth conductive layer CDL4 and the fifth conductive layer CDL5, and may cover the fourth conductive layer CDL4. For example, the fourth insulating layer IL4 may be disposed on the third insulating layer IL3, and electrodes (e.g., a source electrode SE and a drain electrode DE of the transistor T, and a fourth electrode E4 and a fifth electrode E5 of the capacitor C), wires, and/or conductive patterns provided in the fourth conductive layer CDL4. In an embodiment, the fourth insulating layer IL4 may be a single-layer or multi-layer insulating layer including an organic insulating layer. The fourth insulating layer IL4 may include an inorganic insulating layer or may not include an inorganic insulating layer.

The fifth insulating layer IL5 may be disposed between the fifth conductive layer CDL5 and the light emitting element layer LEL, and may cover the fifth conductive layer CDL5. For example, the fifth insulating layer IL5 may be disposed on the fourth insulating layer IL4, and may cover electrodes (e.g., the bridge electrode BRE electrically connected to the transistor T and a sixth electrode E6 of the capacitor C), wires, and/or conductive patterns provided in the fifth conductive layer CDL5. In an embodiment, the fifth insulating layer IL5 may be a single-layer or multi-layer insulating layer including an organic insulating layer. The fifth insulating layer IL5 may include an inorganic insulating layer or may not include an inorganic insulating layer.

In an embodiment, each of the first insulating layer IL1, the second insulating layer IL2, the gate insulating layer GI, and the third insulating layer IL3 may include at least one inorganic insulating layer containing an inorganic insulating material (e.g., silicon nitride, silicon oxide, silicon oxynitride, titanium oxide, aluminum oxide, another inorganic insulating material, or a combination thereof). For example, each of the first insulating layer IL1, the second insulating layer IL2, the gate insulating layer GI, and the third insulating layer IL3 may be a single-layer or multi-layer inorganic insulating layer.

In an embodiment, the first layer IL2a of the second insulating layer IL2 may include silicon nitride, and the second layer IL2b of the second insulating layer IL2 may include silicon oxide or silicon oxynitride. As the second insulating layer IL2 includes the first layer IL2a and the second layer IL2b made of different materials, the insulating properties of the second insulating layer IL2 may be improved or secured. For example, by disposing the second insulating layer IL2 of at least a double layer between the second bottom electrode BE2 and the active layer ACT, which overlap each other with the second insulating layer IL2 disposed therebetween, it is possible to stably insulate the second bottom electrode BE2 and the active layer ACT and to prevent defects such as short circuit defects.

Further, by covering the second conductive layer CDL2 with the first layer IL2a containing silicon nitride which has an excellent hydrogen blocking effect, it may be possible to effectively block hydrogen from being introduced into the semiconductor layer SCL from the first conductive layer CDL1 and/or the second conductive layer CDL2. For example, it may be possible to block hydrogen from being introduced from at least one of the first bottom electrode BE1 or the second bottom electrode BE2 into the active layer ACT disposed above the first bottom electrode BE1 and the second bottom electrode BE2. Accordingly, changes in the characteristics of the transistor T may be prevented, and the operating characteristics of the transistor T may be improved or stabilized. Accordingly, defects in the display panel 110 that may occur due to deterioration of the operating characteristics of the transistor T, such as bright spots or dark spots, may be prevented.

In an embodiment, the thickness of the first layer IL2a of the second insulating layer IL2 may be greater than the thickness of the second layer IL2b of the second insulating layer IL2. In an embodiment, the first layer IL2a of the second insulating layer IL2 may include silicon nitride and may be formed with a thickness of at least about 1000 Å to effectively block hydrogen diffusion. For example, the first layer IL2a of the second insulating layer IL2 may be a silicon nitride layer formed with a thickness in a range of about 1000Å to about 2000Å. Accordingly, it may be possible to secure insulating properties without forming the second insulating layer IL2 to be too thick and at the same time to appropriately block hydrogen from being introduced or diffused into the active layer ACT. Accordingly, the active layer ACT may be protected, and the operating characteristics of the transistor T may be improved or secured.

In an embodiment, the first layer IL3a of the third insulating layer IL3 may include silicon oxide or silicon oxynitride, and the second layer IL3b of the third insulating layer IL3 may include silicon nitride. By first covering the active layer ACT with the first layer IL3a containing silicon oxide or silicon oxynitride, it may be possible to prevent or reduce hydrogen from being introduced or diffused into the active layer ACT from the second layer IL3b of the third insulating layer IL3. Further, by covering the first layer IL3a with the second layer IL3b containing silicon nitride, it may be possible to block hydrogen from being introduced or diffused into the active layer ACT from other surrounding conductive layers, insulating layers, or the like. Accordingly, the active layer ACT may be stably protected and the operating characteristics of the transistor T may be improved or secured.

In an embodiment, the thickness of the first layer IL3a of the third insulating layer IL3 may be greater than the thickness of the second layer IL3b of the third insulating layer IL3. For example, the first layer IL3a of the third insulating layer IL3 may be formed to have a thickness of at least about 1000 Å. For example, the first layer IL3a of the third insulating layer IL3 may be formed to have a thickness in a range of about 1000 Å to about 2000 Å. Accordingly, by securing a separation distance between the second layer IL3b of the third insulating layer IL3 and the active layer ACT, it may be possible to prevent or reduce hydrogen from being introduced into the active layer ACT from the second layer IL3b of the third insulating layer IL3.

In an embodiment, each of the fourth insulating layer IL4 and the fifth insulating layer IL5 may include at least one organic insulating layer containing an organic insulating material (e.g., acrylic resin, epoxy resin, phenolic resin, polyamide resin, polyimide resin, or another organic insulating material). The surfaces (e.g., top surfaces) of the fourth insulating layer IL4 and the fifth insulating layer IL5 may be substantially flat.

In an embodiment, at least one insulating layer provided in the panel circuit layer PCL may be disposed entirely in the display area DA. For example, the first insulating layer IL1, the second insulating layer IL2, the third insulating layer IL3, the fourth insulating layer IL4, and the fifth insulating layer IL5 may be disposed entirely in the display area DA.

In an embodiment, the gate insulating layer GI may be partially disposed only in each pixel area PXA and a portion of the display area DA including the same. In an embodiment, the gate insulating layer GI may include the first gate insulating layer GI1 (also referred to as “first gate insulating pattern”) disposed on a part of each active layer ACT provided in the semiconductor layer SCL, and the second gate insulating layer GI2 (also referred to as “second gate insulating pattern”) disposed on the second insulating layer IL2 without overlapping the active layer ACT. For example, the first gate insulating layer GI1 may be disposed between a portion of the active layer ACT including a channel region CH and the gate electrode GE, and the second gate insulating layer GI2 may be disposed between the third electrode E3 of the capacitor C provided in the third conductive layer CDL3 and the second insulating layer IL2. The first gate insulating layer GI1 and the second gate insulating layer GI2 may extend to each other to form an integrated insulating pattern, or may be individual insulating patterns that may be separated from each other in a plan view. However, the embodiments are not limited thereto. For example, the gate insulating layer GI may be disposed entirely in the display area DA to entirely cover the second insulating layer IL2 and the semiconductor layer SCL.

In an embodiment, the display panel 110 may further include the first bottom electrode BE1 disposed below the transistor T. As an example, the display panel 110 may further include the first bottom electrode BE1 disposed below the second bottom electrode BE2. In an embodiment, the first bottom electrode BE1 may be provided in the first conductive layer CDL1 disposed on the substrate SUB and the barrier layer BR. In an embodiment, the first bottom electrode BE1 may include a first end EP1 that overlaps the active layer ACT.

The first bottom electrode BE1 may overlap the second bottom electrode BE2. Accordingly, a capacitor (e.g., the second capacitor C2 in FIG. 3) may be formed between the first bottom electrode BE1 and the second bottom electrode BE2. For example, the first bottom electrode BE1 may constitute the third capacitor electrode CE3, and the second bottom electrode BE2 may constitute the fourth capacitor electrode. The third capacitor electrode CE3 and the fourth capacitor electrode may form the second capacitor C2 of FIG. 3. In another example, the first bottom electrode BE1 may be formed integrally with (e.g., formed from a same first conductive layer CDL1 as) the first electrode E1 of the first capacitor electrode CE1 to form the first capacitor C1.

The transistor T may include the active layer ACT (also referred to as “active pattern” or “semiconductor pattern”) and the gate electrode GE (e.g., a top-gate electrode) disposed on a part of the active layer ACT. In an embodiment, the transistor T may further include at least one of the source electrode SE or the drain electrode DE. For example, the transistor T may further include the source electrode SE electrically connected to a source region SR of the active layer ACT and the drain electrode DE electrically connected to a drain region DR of the active layer ACT. In another example, the transistor T may not include a separate source electrode and/or a separate drain electrode, and the source region SR and/or the drain region DR of the first active layer ACT may be electrically connected to another circuit element, wire, and/or conductive pattern to function as the source electrode and/or the drain electrode of the transistor T.

In an embodiment, the transistor T may further include the second bottom electrode BE2 (or a bottom-gate electrode) disposed under the active layer ACT. For example, the second bottom electrode BE2 may be electrically connected to an electrode of the transistor T, and may be utilized as a back-gate electrode BG for adjusting the characteristics of the transistor T. Since the second bottom electrode BE2 may be disposed under the active layer ACT, it may be possible to block external light from being incident on the channel region CH of the active layer ACT, and stabilize the operating characteristics of the transistor T.

FIG. 4 discloses an embodiment in which the transistor T may be formed in a double gate structure including the second bottom electrode BE2 and the gate electrode GE that overlap each other in a plan view with the active layer ACT disposed between the gate electrode GE and the second bottom electrode BE2, but embodiments are not limited thereto. For example, the transistor T may include only one of the second bottom electrode BE2 and the gate electrode GE. As an example, the transistor T may be formed in a top-gate structure including the single gate electrode GE disposed above the active layer ACT, or may also be formed in a bottom-gate structure including the second bottom electrode BE2 disposed below the active layer ACT.

In an embodiment, the transistor T may be an N-type transistor. For example, the transistor T may be an N-type oxide transistor.

The second bottom electrode BE2 may be provided in the second conductive layer CDL2 disposed on the first insulating layer IL1. The second conductive layer CDL2 may be disposed between the first insulating layer IL1 and the second insulating layer IL2. The second bottom electrode BE2 may overlap the active layer ACT and the gate electrode GE in a plan view. For example, the second bottom electrode BE2 may be disposed under the active layer ACT to overlap at least a portion of the active layer ACT including the channel region CH, and may face the gate electrode GE with the active layer ACT disposed therebetween.

In embodiments, the first bottom electrode BE1 and the second bottom electrode BE2 may include respective ends that overlap the active layer ACT, and the ends may not overlap in the thickness direction of the substrate SUB. For example, the first bottom electrode BE1 may include the first end EP1 overlapping the active layer ACT, and the second bottom electrode BE2 may include the second end EP2 overlapping the active layer ACT and adjacent to the first end EP1 of the first bottom electrode BE1. The first end EP1 of the first bottom electrode BE1 and the second end EP2 of the second bottom electrode BE2 may not overlap each other in the thickness direction (e.g., the third direction D3) of the substrate SUB (or in a plan view). For example, the first end EP1 and the second end EP2 may be disposed at positions spaced apart from each other when viewed in a plan view defined by the first direction D1 and the second direction D2.

In an embodiment, the second bottom electrode BE2 may be electrically connected to the source electrode SE or the gate electrode GE of the transistor T. For example, the transistor T may be the driving transistor of the pixel PX, and the second bottom electrode BE2 of the transistor T may be electrically connected to the source electrode SE of the transistor T through a first contact hole CNT1 penetrating the second insulating layer IL2 and the third insulating layer IL3. In another example, the transistor T may be the switching transistor of the pixel PX, and the second bottom electrode BE2 of the transistor T may be electrically connected to the gate electrode GE of the transistor T.

The active layer ACT may be provided in the semiconductor layer SCL. The semiconductor layer SCL may be disposed on the second insulating layer IL2 covering the second conductive layer CDL2, and may be covered by the gate insulating layer GI and the third insulating layer IL3.

The active layer ACT may include the channel region CH, the source region SR, and the drain region DR spaced apart from each other with the channel region CH disposed between the source region SR and the drain region DR. For example, the source region SR and the drain region DR may be located on both sides of the channel region CH. The channel region CH may be a region that maintains semiconductor characteristics without becoming conductive. The source region SR and the drain region DR, which may be regions that have become conductive, may have a carrier concentration (e.g., electron concentration) higher than that of the channel region CH.

The active layer ACT may overlap the second bottom electrode BE2 and the gate electrode GE. For example, a portion of the active layer ACT including the channel region CH may overlap the second bottom electrode BE2 and the gate electrode GE.

In an embodiment, the active layer ACT may include an oxide semiconductor. For example, the active layer ACT may include an oxide semiconductor containing at least one of indium (In), gallium (Ga), zinc (Zn), tin (Sn), or hafnium (Hf), or other oxide semiconductors. In an embodiment, the active layer ACT may include at least one of zinc oxide (ZnO), zinc-tin oxide (ZTO), indium-zinc oxide (IZO), indium oxide (InO or In₂O₃), titanium oxide (TiO or TiO₂), indium-gallium oxide (IGO), indium-gallium-zinc oxide (IGZO), indium-gallium-tin oxide (IGTO), indium-zinc-tin oxide (IZTO), or indium-tin-gallium-zinc oxide (ITGZO), or other oxide semiconductors.

In an embodiment, the active layer ACT may be formed of a high-mobility oxide semiconductor (e.g., an oxide semiconductor material with mobility of about 20 cm²/Vs or at least about 30 cm²/Vs). For example, the active layer ACT may be formed of indium-gallium-zinc oxide (IGZO) or indium-tin-gallium-zinc oxide (ITGZO), and may have mobility of at least about 20 cm²/Vs. In case that the active layer ACT is formed of a high-mobility oxide semiconductor, the conductivity of the source region SR and the drain region DR may be appropriately and/or readily secured without performing an additional doping process. Further, in case that the active layer ACT is formed of a high-mobility oxide semiconductor, it may be possible to form the transistor T in a fine size (e.g., a size including the active layer ACT having a width and/or length in a range of about several micrometers to about several tens of micrometers) and appropriately secure the mobility of the transistor T.

The first gate insulating layer GI1 may be disposed on the active layer ACT. For example, the first gate insulating layer GI1 may be disposed between the active layer ACT and the gate electrode GE.

In an embodiment, the first gate insulating layer GI1 may cover a portion of the active layer ACT including a portion overlapping the gate electrode GE and expose another portion of the active layer ACT. For example, the first gate insulating layer GI1 may be disposed on a portion of the active layer ACT including the channel region CH, and may expose the source region SR and the drain region DR of the active layer ACT.

Since the first gate insulating layer GI1 exposes the source region SR and the drain region DR, the source region SR and the drain region DR may become appropriately and/or readily conductive in the manufacturing process of the display panel 110. For example, in the step of etching the gate insulating layer GI to expose at least a part of the source region SR and at least a part of the drain region DR, oxygen vacancies may occur in the source region SR and the drain region DR by an etching gas or the like. Accordingly, the source region SR and the drain region DR may become appropriately conductive in a subsequent process (e.g., a process of forming the third insulating layer IL3) without performing a separate doping process.

In an embodiment, in order to limit the carrier concentration of the source region SR and the drain region DR and/or the mobility of the active layer ACT to an appropriate range, an oxygen supply layer may be formed between the first gate insulating layer GI1 and the gate electrode GE. For example, the transistor T may further include the oxygen supply layer disposed between the first gate insulating layer GI1 and the gate electrode GE and containing an oxide semiconductor. The active layer ACT and the oxygen supply layer of the transistor T may contain a same oxide semiconductor or different oxide semiconductors.

A gate electrode GE may be disposed on the first gate insulating layer GI1. The gate electrode GE may be provided in the third conductive layer CDL3. The third conductive layer CDL3 may be disposed on the second insulating layer IL2 and the gate insulating layer GI, and may be covered by the third insulating layer IL3.

The gate electrode GE may be disposed on the active layer ACT to overlap the channel region CH. The gate electrode GE and the active layer ACT may be separated and/or spaced apart from each other with the first gate insulating layer GI1 disposed between the gate electrode GE and the active layer ACT.

The third insulating layer IL3 may be disposed on the gate electrode GE. The third insulating layer IL3 may cover the active layer ACT, the gate insulating layer GI, and the gate electrode GE.

The source electrode SE and the drain electrode DE may be disposed on the third insulating layer IL3. The source electrode SE and the drain electrode DE may be provided in the fourth conductive layer CDL4. The fourth conductive layer CDL4 may be disposed between the third insulating layer IL3 and the fourth insulating layer IL4. In an embodiment, each of the patterns of the fourth conductive layer CDL4 may be formed of a double layer (e.g., a double layer including a lower layer containing aluminum (Al) and an upper layer containing titanium (Ti)) or may be formed of a triple layer (e.g., a triple layer of aluminum (Al)/titanium (Ti)/aluminum (Al).

The source electrode SE may be electrically connected to a part of the active layer ACT. For example, the source electrode SE may be electrically connected to the source region SR of the active layer ACT through a second contact hole CNT2 penetrating the third insulating layer IL3. In an embodiment, the source electrode SE may be electrically connected to the second bottom electrode BE2 through the first contact hole CNT1.

The drain electrode DE may be electrically connected to another part of the active layer ACT. For example, the drain electrode DE may be electrically connected to the drain region DR of the active layer ACT through a third contact hole CNT3 penetrating the third insulating layer IL3.

In an embodiment, at least one transistor T provided in each pixel area PXA may be electrically connected to the light emitting element ED disposed on the transistor T. For example, at least one transistor T (e.g., the first transistor T1) provided in each pixel area PXA may be electrically connected to the bridge electrode BRE disposed on the fourth insulating layer IL4 covering the fourth conductive layer CDL4. For example, the source electrode SE (or the drain electrode DE) of the first transistor T1 provided in each pixel area PXA may be electrically connected to the bridge electrode BRE on the fourth insulating layer IL4 through a seventh contact hole CNT7 penetrating the fourth insulating layer IL4. The at least one transistor T may be electrically connected to the light emitting element ED disposed on the fifth insulating layer IL5 through the bridge electrode BRE.

The bridge electrode BRE may be provided in the fifth conductive layer CDL5. The bridge electrode BRE may be electrically connected to a first electrode ET1 of the light emitting element ED provided in the light emitting element layer LEL through a ninth contact hole CNT9 penetrating the fifth insulating layer IL5.

The fifth conductive layer CDL5 may be disposed between the fourth insulating layer IL4 and the fifth insulating layer IL5. For example, the fifth conductive layer CDL5 may be disposed on the fourth insulating layer IL4 and covered by the fifth insulating layer IL5. In an embodiment, each of the patterns of the fifth conductive layer CDL5 may be formed of a double layer (e.g., a double layer including a lower layer containing aluminum (Al) and an upper layer containing titanium (Ti)) or may be formed of a triple layer (e.g., a triple layer of aluminum (Al)/titanium (Ti)/aluminum (Al).

The capacitor C may include capacitor electrodes that form electrostatic capacitance. For example, the first capacitor C1 of FIG. 3 may include the first capacitor electrode CE1 and a second capacitor electrode CE2. In an embodiment, the first capacitor C1 may have a multi-layer structure including multi-layer electrodes (or sub-electrodes). Accordingly, the capacitance of the first capacitor C1 may be appropriately secured by efficiently utilizing the area of the pixel area PXA.

In embodiments, the first capacitor C1 may include a first electrode E1 provided in the first conductive layer CDL1, a second electrode E2 provided in the second conductive layer CDL2, the third electrode E3 provided in the third conductive layer CDL3, a fourth electrode E4 provided in the fourth conductive layer CDL4. In an embodiment, the first capacitor C1 may further include at least one of a fifth electrode E5 provided in the fourth conductive layer CDL4 while being spaced apart from the fourth electrode E4, or a sixth electrode E6 provided in the fifth conductive layer CDL5.

In an embodiment, the fourth electrode E4 may overlap the first electrode E1, and may be electrically connected to the first electrode E1 through a fourth contact hole CNT4 penetrating the first insulating layer IL1, the second insulating layer IL2, and the third insulating layer IL3. In an embodiment, the fourth electrode E4 may also overlap the third electrode E3, and may be electrically connected to the third electrode E3 through a fifth contact hole CNT5 penetrating the third insulating layer IL3. For example, the fourth electrode E4 may be electrically connected individually and/or in parallel to the first electrode E1 and the third electrode E3 through the fourth contact hole CNT4 and the fifth contact hole CNT5, respectively. The first electrode E1 and the third electrode E3 may be electrically connected to each other through the fourth electrode E4. The first electrode E1, the third electrode E3, and the fourth electrode E4 may form the first capacitor electrode CE1 of the first capacitor C1.

In an embodiment, the third electrode E3 may be electrically connected to the gate electrode GE of the first transistor T1 located in each pixel area PXA. For example, the third electrode E3 in the third conductive layer CDL3 and the gate electrode GE of the first transistor T1 may be integral with each other. For example, the third electrode E3 and the gate electrode GE of the first transistor T1 may be electrically connected to each other to form an integrated electrode when viewed in a plan view defined by the first direction D1 and the second direction D2. The first gate insulating layer GI1 located under the gate electrode GE of the first transistor T1 and the second gate insulating layer GI2 located under the third electrode E3 may extend to each other to form an integrated insulating pattern.

The second electrode E2 may overlap at least one of the first electrode E1, the third electrode E3, or the fourth electrode E4 and may form a capacitance between itself and the at least one electrode. The second electrode E2 may constitute the second capacitor electrode CE2.

In an embodiment, the second electrode E2 may be electrically connected to the source electrode SE of the first transistor T1 located in each pixel area PXA. For example, the second electrode E2 and the second bottom electrode BE2 of the first transistor T1 may be provided in the second conductive layer CDL2 and may be integral with each other, and may be electrically connected to the source electrode SE of the first transistor T1 through the first contact hole CNT1.

The fifth electrode E5 may overlap the second electrode E2, and may be connected (e.g., directly electrically connected) to the second electrode E2 through a sixth contact hole CNT6 penetrating the second insulating layer IL2 and the third insulating layer IL3. The fifth electrode E5 may constitute the second capacitor electrode CE2 together with the second electrode E2. The fifth electrode E5 and the source electrode SE of the first transistor T1 located in each pixel area PXA may be integral with each other, or may be formed separately from each other.

The sixth electrode E6 may overlap the fifth electrode E5, and may be connected (e.g., directly electrically connected) to the fifth electrode E5 through an eighth contact hole CNT8 penetrating the fourth insulating layer IL4. The sixth electrode E6 may constitute the second capacitor electrode CE2 together with the second electrode E2 and the fifth electrode E5. The sixth electrode E6 and the bridge electrode BRE located in each pixel area PXA may be integral with each other, or may be formed separately from each other.

In an embodiment, the display panel 110 may include multi-layer wires including sub-wires provided in at least two conductive layers provided in the panel circuit layer PCL, similarly to the first capacitor electrode CE1 and/or the second capacitor electrode CE2. For example, at least one of the wires provided in the display panel 110 may have a multi-layer structure including at least two sub-wires among a first sub-wire provided in the first conductive layer CDL1, a second sub-wire provided in the second conductive layer CDL2, a third sub-wire provided in the third conductive layer CDL3, a fourth sub-wire provided in the fourth conductive layer CDL4, and a fifth sub-wire provided in the fifth conductive layer CDL5. Accordingly, the resistance of the wires may be lowered.

The light emitting element layer LEL may be disposed on the panel circuit layer PCL. For example, the light emitting element layer LEL may be disposed on the fifth insulating layer IL5, and may be located at least in the display area DA.

The light emitting element layer LEL may include the light emitting element ED for each of the pixels PX. For example, the light emitting element layer LEL may include a pixel defining layer PDL (also referred to as “bank”) that partitions the emission areas of the pixels PX and the light emitting element ED located in each emission area. In an embodiment, the light emitting element layer LEL may further include a spacer SPC disposed on a part of the pixel defining layer PDL.

Each light emitting element ED may include a first electrode ET1 located in each emission area, and a light emitting layer EML and a second electrode ET2 sequentially disposed on the first electrode ET1. The first electrode ET1 of the light emitting element ED may be electrically connected to at least one transistor (e.g., the first transistor T1) included in the corresponding pixel PX.

The first electrode ET1 of the light emitting element ED may be a single-layer or multi-layer electrode including at least one conductive material. In an embodiment, the display panel 110 may be a top emission type display panel, and the first electrode ET1 may include a reflective electrode layer having high reflectivity.

The light emitting layer EML of the light emitting element ED may include a high molecular material or a low molecular material. Light emitted from the light emitting layer EML may contribute to image display.

The second electrode ET2 of the light emitting element ED may include a conductive material. In an embodiment, the second electrode ET2 may be a common layer formed across the entire display area DA to cover the light emitting layer EML and the pixel defining layer PDL. In an embodiment, the display panel 110 may be a top emission type display panel, and the second electrode ET2 may include a transparent or translucent electrode layer.

The pixel defining layer PDL may have an opening corresponding to each emission area and may surround the emission area. For example, the pixel defining layer PDL may be formed to cover an edge of the first electrode ET1 of the light emitting element ED and may include an opening exposing the remaining portion of the first electrode ET1. A region where the exposed first electrode ET1 and the light emitting layer EML overlap may be the emission area of each pixel PX. In an embodiment, the pixel defining layer PDL may include at least one organic insulating layer containing an organic insulating material.

The spacer SPC may be disposed on a part of the pixel defining layer PDL. The spacer SPC may include at least one organic insulating layer containing an organic insulating material. The spacer SPC and the pixel defining layer PDL may include a same material or may include a different material. The pixel defining layer PDL and the spacer SPC may be sequentially formed through individual mask processes, or may be simultaneously and/or integrally formed using a halftone mask.

The encapsulation layer ENL may be disposed on the light emitting element layer LEL. The encapsulation layer ENL may cover the light emitting element layer LEL in the display area DA and may extend to the non-display area NDA to be in contact with the panel circuit layer PCL. The encapsulation layer ENL may block the permeation of oxygen or moisture into the light emitting element layer LEL, and may reduce electrical and/or physical impact to the panel circuit layer PCL and the light emitting element layer LEL.

In an embodiment, the encapsulation layer ENL may include a first encapsulation layer ENL1, a second encapsulation layer ENL2, and a third encapsulation layer ENL3 sequentially disposed on the light emitting element layer LEL. Each of the first encapsulation layer ENL1 and the third encapsulation layer ENL3 may be an inorganic encapsulation layer containing an inorganic material. The second encapsulation layer ENL2 may be an organic encapsulation layer containing an organic material.

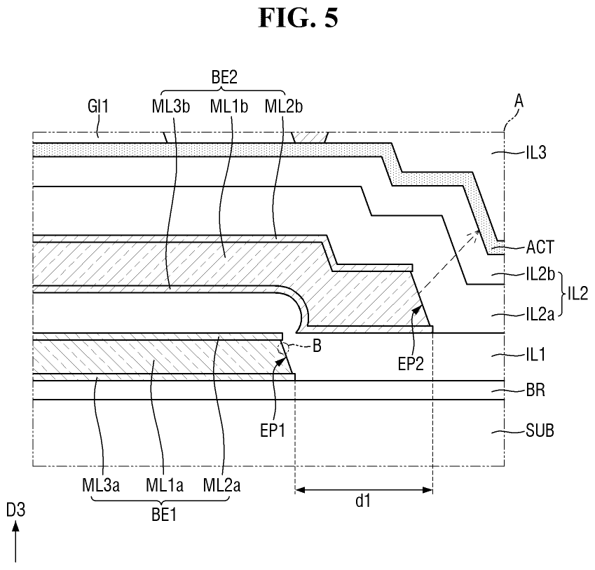

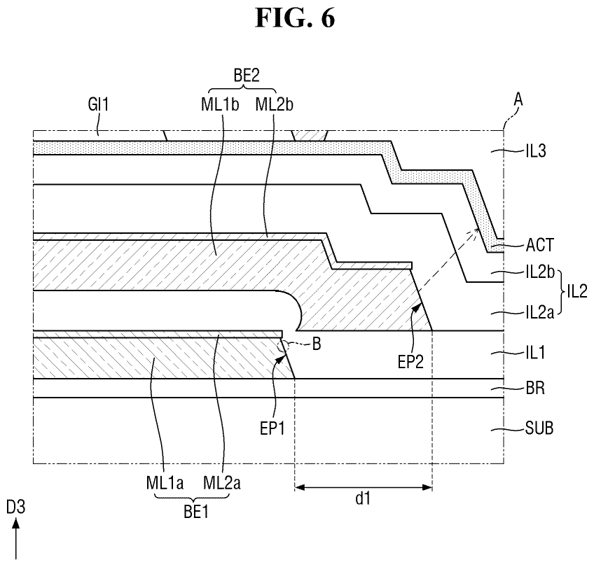

FIG. 5 is a schematic cross-sectional view showing area A of FIG. 4 in detail. FIG. 6 is a schematic cross-sectional view showing area A of FIG. 4 in detail. FIGS. 5 and 6 illustrate different embodiments with respect to the first bottom electrode BE1 and the second bottom electrode BE2.

Referring to FIGS. 5 and 6 in addition to FIG. 4, the first bottom electrode BE1 and the second bottom electrode BE2 may be formed of at least double-layer electrodes. For example, the first bottom electrode BE1 and the second bottom electrode BE2 may be formed of triple-layer electrodes including each of first metal layers ML1a and ML1b, each of second metal layers ML2a and ML2b disposed above the first metal layers ML1a and ML1b, and each of the third metal layers ML3a and ML3b disposed below the first metal layers ML1a and ML1b as illustrated in FIG. 5. In another example, the first bottom electrode BE1 and the second bottom electrode BE2 may be formed of double-layer electrodes including each of the first metal layers ML1a and ML1b and each of the second metal layers ML2a and ML2b disposed above the first metal layers ML1a and ML1b as illustrated in FIG. 6.

In an embodiment, each of the first metal layers ML1a and ML1b of the first bottom electrode BE1 and the second bottom electrode BE2 may include aluminum (Al) having a relatively low resistance. Each of the first metal layers ML1a and ML1b of the first bottom electrode BE1 and the second bottom electrode BE2 may include a low-resistance metal other than aluminum (Al). Each of the first metal layers ML1a and ML1b of the first bottom electrode BE1 and the second bottom electrode BE2 may have a relatively large thickness as compared with the second metal layers ML2a and ML2b and the third metal layers ML3a and ML3b.

Each of the second metal layers ML2a and ML2b of the first bottom electrode BE1 and the second bottom electrode BE2 may include titanium (Ti) that may block ions of each of the first metal layers ML1a and ML1b from diffusing into the periphery. Each of the second metal layers ML2a and ML2b of the first bottom electrode BE1 and the second bottom electrode BE2 may include a capping metal other than titanium (Ti). In an embodiment, the second metal layer ML2a of the first bottom electrode BE1 may completely cover the top surface of the first metal layer ML1a of the first bottom electrode BE1, and the second metal layer ML2b of the second bottom electrode BE2 may completely cover the top surface of the first metal layer ML1b of the second bottom electrode BE2.

The second metal layers ML2a and ML2b of the first bottom electrode BE1 and the second bottom electrode BE2 cap the top surfaces of the first metal layers ML1a and ML1b of the first bottom electrode BE1 and the second bottom electrode BE2 respectively so that a void or seam may be suppressed from occurring in the top surfaces of the first metal layers ML1a and ML1b or the periphery thereof (e.g., the first insulating layer IL1 and the second insulating layer IL2). Further, the second metal layers ML2a and ML2b may block hydrogen from diffusing in an upward direction (e.g., in the third direction D3) from the first metal layers ML1a and ML1b.

Each of the third metal layers ML3a and ML3b of the first bottom electrode BE1 and the second bottom electrode BE2 may include titanium (Ti). Each of the third metal layers ML3a and ML3b of the first bottom electrode BE1 and the second bottom electrode BE2 may include a capping metal other than titanium (Ti). In an embodiment, the third metal layer ML3a of the first bottom electrode BE1 may completely cover the bottom surface of the first metal layer ML1a of the first bottom electrode BE1, and the third metal layer ML3b of the second bottom electrode BE2 may completely cover the bottom surface of the first metal layer ML1b of the second bottom electrode BE2.

The first metal layers ML1a and ML1b of the first bottom electrode BE1 and the second bottom electrode BE2 may be formed on the third metal layers ML3a and ML3b of the first bottom electrode BE1 and the second bottom electrode BE2 so that a void or seam may be suppressed from occurring in the bottom surfaces of the first metal layers ML1a and ML1b or the periphery thereof. Further, hydrogen diffusion in the third direction D3 may be blocked by the third metal layers ML3a and ML3b. For example, it may be possible to block hydrogen from diffusing from the first metal layers ML1a and ML1b into the periphery, or hydrogen from diffusing from the lower portions of the first bottom electrode BE1 and the second bottom electrode BE2 into the first bottom electrode BE1, the second bottom electrode BE2, and the like.

The first bottom electrode BE1 and the second bottom electrode BE2 may include the first end EP1 and the second end EP2 that overlap the active layer ACT and may be adjacent to each other. The first metal layers ML1a and ML1b of the first bottom electrode BE1 and the second bottom electrode BE2 may be exposed at the first end EP1 and the second end EP2.

At the first end EP1 and the second end EP2 at which the first metal layers ML1a and ML1b are exposed, a void or seam may occur in the first bottom electrode BE1, the second bottom electrode BE2, and/or the periphery thereof. For example, a void or seam may occur in a portion in which the first metal layers ML1a and ML1b are exposed, such as area B in FIGS. 5 and 6, or the insulating layer of the periphery thereof (e.g., the first insulating layer IL1 and/or the second insulating layer IL2). A void or seam may form a path for hydrogen to move or diffuse.

In embodiments, the first bottom electrode BE1 and the second bottom electrode BE2 may be disposed to alleviate a void or seam and increase a length of the hydrogen movement path. Accordingly, diffusion of hydrogen between layers of the display panel 110 may be prevented or reduced, and the active layer ACT may be appropriately protected.

For example, the first end EP1 and the second end EP2 may not overlap each other in the third direction D3 (or in a plan view). The first end EP1 and the second end EP2 may be spaced apart from each other by a first distance d1 of at least a distance (e.g., at least a predetermined or selectable distance) when viewed in a plan view (e.g., a plane defined by the first direction D1 and the second direction D2) perpendicular to the third direction D3. In an embodiment, the first end EP1 and the second end EP2 may be spaced apart from each other by at least a distance (e.g., at least a predetermined or selectable distance) in each of the first direction D1 and the second direction D2.

In an embodiment, the first end EP1 and the second end EP2 may be spaced apart from each other by a distance of at least about 0.6 μm in a plan view. For example, the first end EP1 and the second end EP2 may be spaced apart from each other by at least a distance of about 0.6 μm in each of the first direction D1 and the second direction D2.

In an embodiment, a part of the second bottom electrode BE2 may overlap the first end EP1 of the first bottom electrode BE1. Further, the second end EP2 of the second bottom electrode BE2 may extend from a part of the second bottom electrode BE2 to the outside of (or may not overlap) the first end EP1. For example, in a plan view, the second end EP2 of the second bottom electrode BE2 may be positioned outside the first end EP1.

According to embodiments, the first end EP1 and the second end EP2 may be disposed to be spaced apart from each other by at least a distance (e.g., at least a predetermined or selectable distance), so that the second insulating layer IL2 may be formed in a shape having a stepped portion corresponding to the first end EP1 and the second end EP2. Accordingly, a separation distance between the first end EP1 and the second end EP2 and the active layer ACT disposed on the second insulating layer IL2 may be appropriately secured. For example, as the second insulating layer IL2 may be formed to have a stepped portion corresponding to the first end EP1 and the second end EP2 as indicated by a dotted arrow in FIGS. 5 and 6, it may be possible to increase a distance of the movement path of hydrogen that may diffuse or be introduced into the active layer ACT from the second end EP2 or the like. A portion of the second bottom electrode BE2 including the second end EP2 may be disposed between the first end EP1 and the active layer ACT so that it may be possible to block hydrogen from diffusing from the first end EP1 or the like to the active layer ACT.

Further, according to embodiments, although a seam in the form of connected voids occur around the first end EP1 and/or the second end EP2, it may be possible to prevent the seam from extending to an area close to the active layer ACT. For example, a seam that occurs around the first end EP1 may be blocked by the second bottom electrode BE2 and may no longer extend, and a seam that occurs around the first end EP1 and a seam that occurs around the second end EP2 may not extend to each other. Accordingly, the seam that may occur between the first bottom electrode BE1 and the second bottom electrode BE2 and the active layer ACT may be alleviated or reduced, and it may be possible to block or reduce hydrogen from diffusing or being introduced into the active layer ACT.

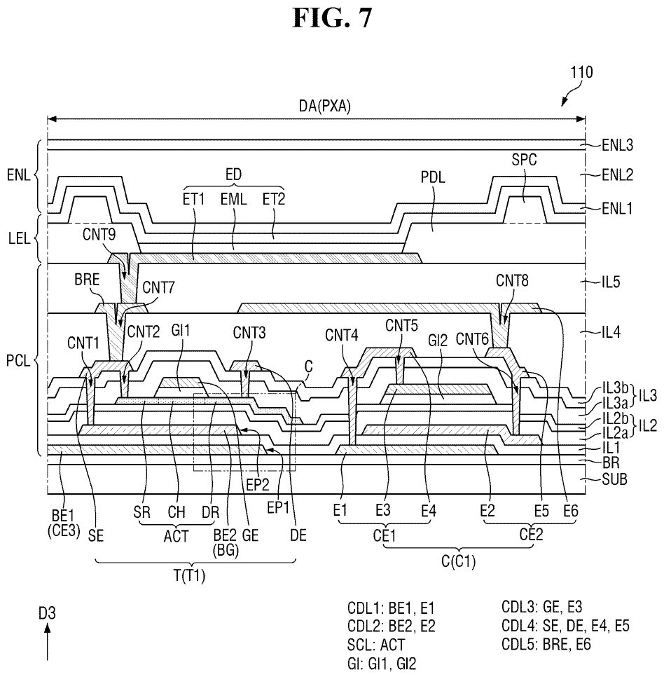

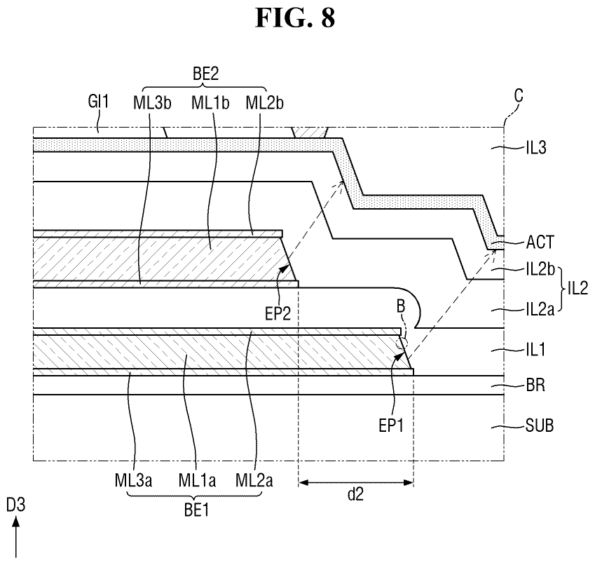

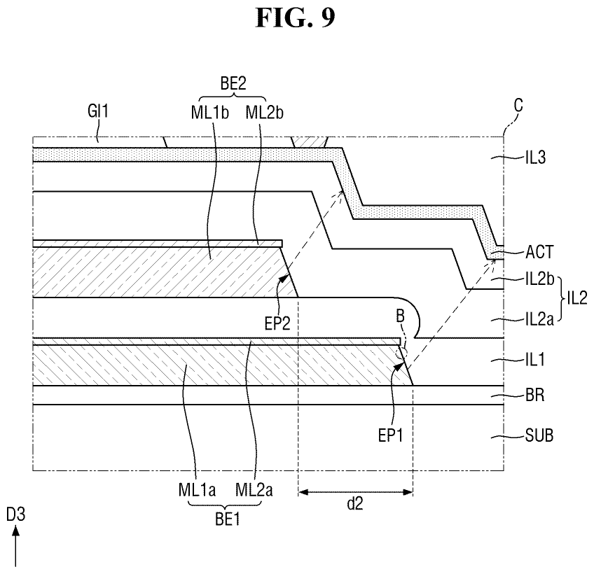

FIG. 7 is a schematic cross-sectional view illustrating the display panel 110 according to an embodiment. FIG. 8 is a schematic cross-sectional view showing area C of FIG. 7 in detail. FIG. 9 is a schematic cross-sectional view showing area C of FIG. 7 in detail. FIGS. 7 to 9 illustrate an embodiment different from the embodiment of FIGS. 4 to 6 with respect to the disposition of the first bottom electrode BE1 and the second bottom electrode BE2.

Referring to FIGS. 7 to 9, a part of the first bottom electrode BE1 may overlap the second end EP2 of the second bottom electrode BE2. Further, the first end EP1 of the first bottom electrode BE1 may extend from a part of the first bottom electrode BE1 to the outside of (or may not overlap) the second end EP2. For example, in a plan view, the first end EP1 of the first bottom electrode BE1 may be positioned outside the second end EP2. Accordingly, the first end EP1 and the second end EP2 may not overlap each other in the third direction D3.

The first end EP1 and the second end EP2 may be spaced apart from each other by a second distance d2 in a plan view. In an embodiment, the second distance d2 may be at least about 0.6 μm. For example, the first end EP1 and the second end EP2 may be spaced apart from each other by a distance of at least about 0.6 μm in each of the first direction D1 and the second direction D2.

According to embodiments, the first end EP1 and the second end EP2 may be disposed to be spaced apart from each other by a distance (e.g., predetermined or selectable distance), so that the second insulating layer IL2 may be formed in a shape having a stepped portion corresponding to the first end EP1 and the second end EP2. Accordingly, a separation distance may be appropriately secured between the first end EP1 and the second end EP2, and the active layer ACT, and it may be possible to block or reduce hydrogen from diffusing into the active layer ACT from the first end EP1, the second end EP2, or the like. For example, as the second insulating layer IL2 may be formed to have a stepped portion corresponding to the first end EP1 and the second end EP2, as indicated by dotted arrows in FIGS. 8 and 9, it may be possible to increase the distance of the movement path of hydrogen that may diffuse or be introduced into the active layer ACT from the first end EP1, the second end EP2, or the like. Further, according to embodiments, the seam that may occur between the first bottom electrode BE1 and the second bottom electrode BE2 and the active layer ACT may be alleviated or reduced, and it may be possible to block or reduce hydrogen from diffusing or being introduced into the active layer ACT.

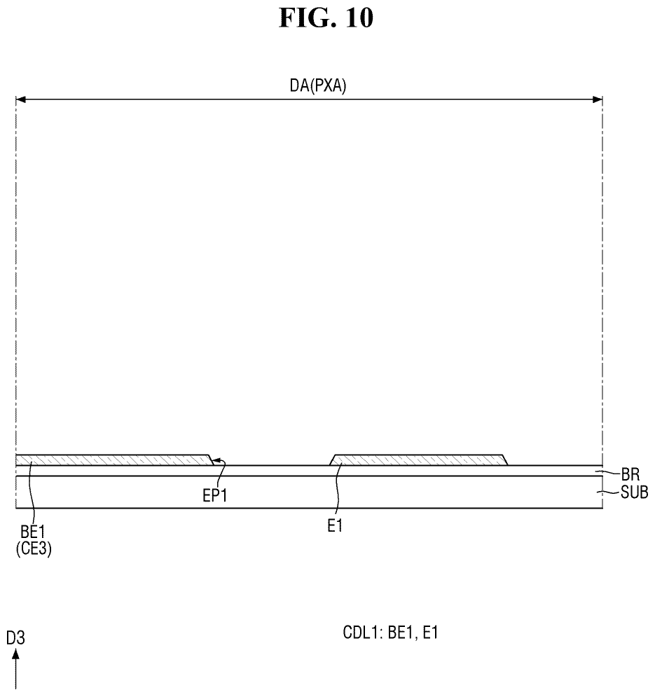

FIGS. 10 to 18 are schematic cross-sectional views illustrating a method for manufacturing the display device 100 according to an embodiment. For example, FIGS. 10 to 18 sequentially show steps of forming the panel circuit layer PCL including the transistor T and the capacitor C among the steps of manufacturing the display panel 110 of FIG. 4. The display panel 110 of FIG. 7 may be manufactured in substantially the same manner as the display panel 110 of FIG. 4 except that the relative sizes and/or positions or the like of the first bottom electrode BE1 and the second bottom electrode BE2 may be partially changed.

Referring to FIG. 10 in addition to FIGS. 1 to 9, the substrate SUB including the display area DA may be prepared, and the barrier layer BR may be selectively formed on the substrate SUB. The display area DA may include the pixel area PXA.

Thereafter, the first conductive layer CDL1 including the first bottom electrode BE1 and the first electrode E1 may be formed on the barrier layer BR (or the substrate SUB). The first bottom electrode BE1 may include the first end EP1.

The patterns (e.g., electrodes, conductive patterns, and/or at least one wire provided in the first conductive layer CDL1) of the first conductive layer CDL1 including the first bottom electrode BE1 and the first electrode E1 may be formed by a film forming process (e.g., a deposition process) of a conductive film using at least one conductive material exemplified above and a patterning process (e.g., an etching process using a mask) of the conductive film. In an embodiment, each of the patterns of the first conductive layer CDL1 may be formed of a double layer including the first metal layer ML1a and the second metal layer ML2a, or may be formed of a triple layer including the first metal layer ML1a, the second metal layer ML2a, and the third metal layer ML3a.

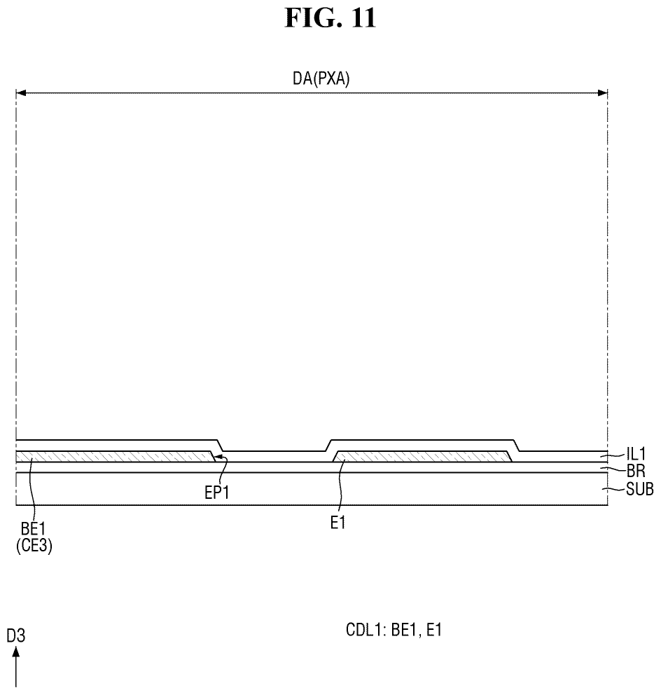

Referring to FIG. 11, the first insulating layer IL1 covering the first conductive layer CDL1 may be formed on the substrate SUB. For example, the first insulating layer IL1 may be formed on the patterns of the first conductive layer CDL1 including the first bottom electrode BE1 and the first electrode E1. The first insulating layer IL1 may be formed by a film forming process of an insulating film using at least one insulating material (e.g., an inorganic insulating material) exemplified above.

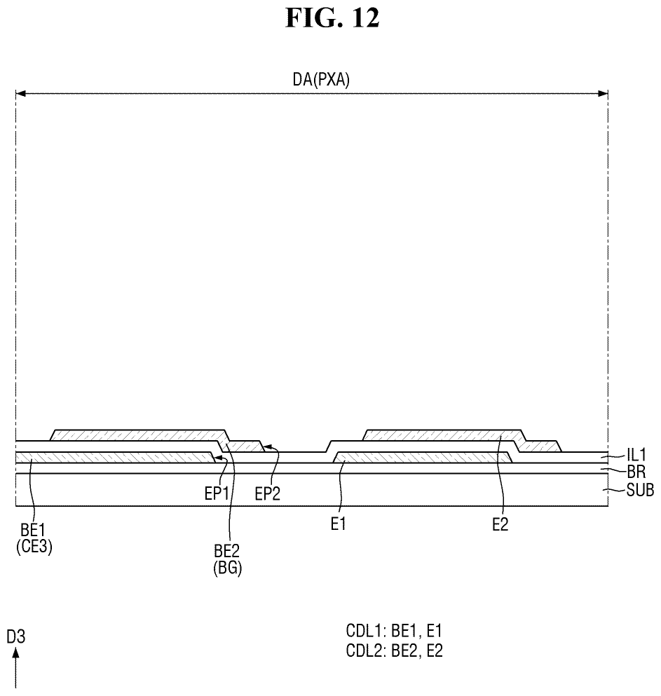

Referring to FIG. 12, the second conductive layer CDL2 including the second bottom electrode BE2 and the second electrode E2 may be formed on the first insulating layer IL1. The second bottom electrode BE2 may include the second end EP2 adjacent to the first end EP1 of the first bottom electrode BE1.

In embodiments, the first bottom electrode BE1 and the second bottom electrode BE2 may be formed such that the first end EP1 and the second end EP2 do not overlap in the thickness direction (e.g., the third direction D3 or a plan view) of the substrate SUB. In an embodiment, the first end EP1 and the second end EP2 may be spaced apart from each other by a distance of at least about 0.6 μm when viewed in a plan view (e.g., a plane defined by the first direction D1 and the second direction D2 perpendicular to the third direction D3). For example, the first end EP1 and the second end EP2 may be spaced apart from each other by a distance of at least about 0.6 μm in each of the first direction D1 and the second direction D2.

The patterns (e.g., electrodes, conductive patterns, and/or at least one wire provided in the second conductive layer CDL2) of the second conductive layer CDL2 including the second bottom electrode BE2 and the second electrode E2 may be formed by a film forming process (e.g., a deposition process) of a conductive film using at least one conductive material exemplified above and a patterning process (e.g., an etching process using a mask) of the conductive film. In an embodiment, each of the patterns of the second conductive layer CDL2 may be formed of a double layer including the first metal layer ML1b and the second metal layer ML2b, or may be formed of a triple layer including the first metal layer ML1b, the second metal layer ML2b, and the third metal layer ML3b.

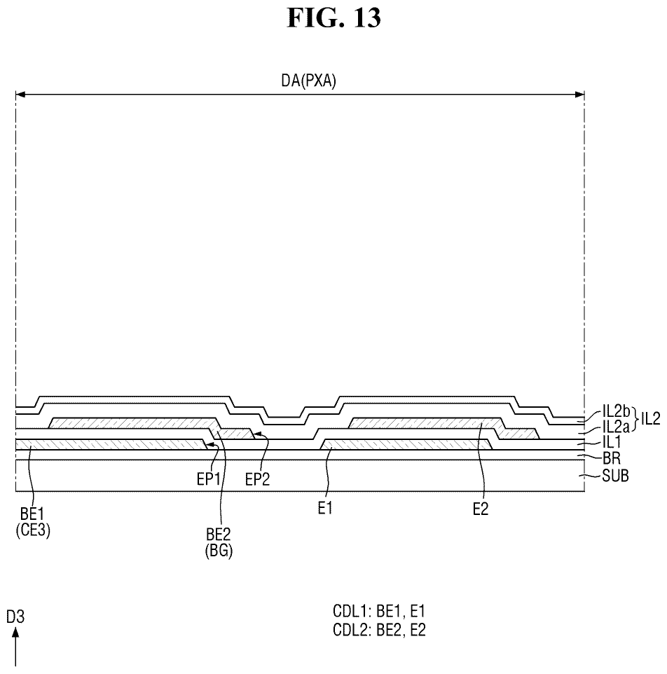

Referring to FIG. 13, the second insulating layer IL2 covering the second conductive layer CDL2 may be formed on the first insulating layer IL1. For example, the second insulating layer IL2 may be formed on the patterns of the second conductive layer CDL2 including the second bottom electrode BE2 and the second electrode E2. The second insulating layer IL2 may be formed by a film forming process of an insulating film using at least one insulating material (e.g., an inorganic insulating material) exemplified above.

In an embodiment, the second insulating layer IL2 may be formed of at least a double layer including the first layer IL2a and the second layer IL2b. As an example, the first layer IL2a including silicon nitride and the second layer IL2b including silicon oxide or silicon oxynitride may be sequentially formed on the first insulating layer ILI and the second conductive layer CDL2 so that the second insulating layer IL2 of a double layer may be formed.

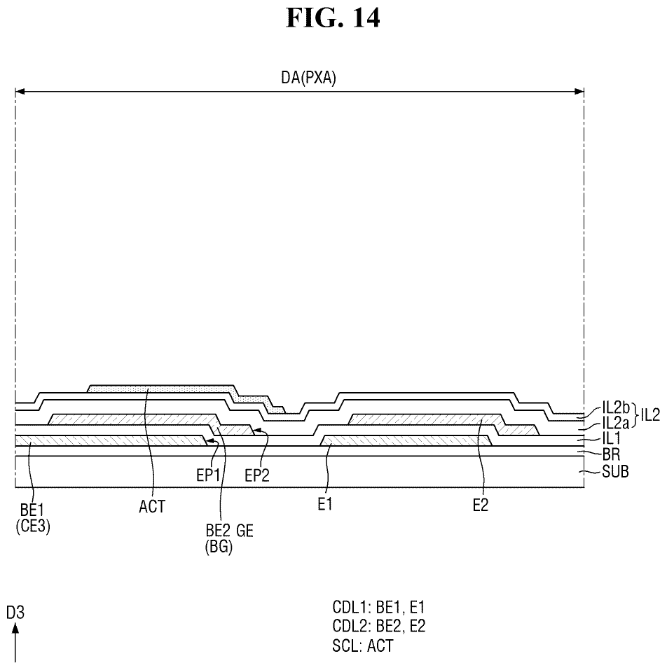

Referring to FIGS. 14 to 17, the transistor T may be formed on the second insulating layer IL2. For example, first, as illustrated in FIG. 14, the semiconductor layer SCL including the active layer ACT may be formed on the second insulating layer IL2. The active layer ACT may be formed in each transistor area.

The active layer ACT may be formed to overlap the second bottom electrode BE2. In an embodiment, the active layer ACT may be formed of an oxide semiconductor. For example, the active layer ACT may be formed by a film forming process and a patterning process (e.g., an etching process using a mask) of a semiconductor layer using at least one oxide semiconductor exemplified above.

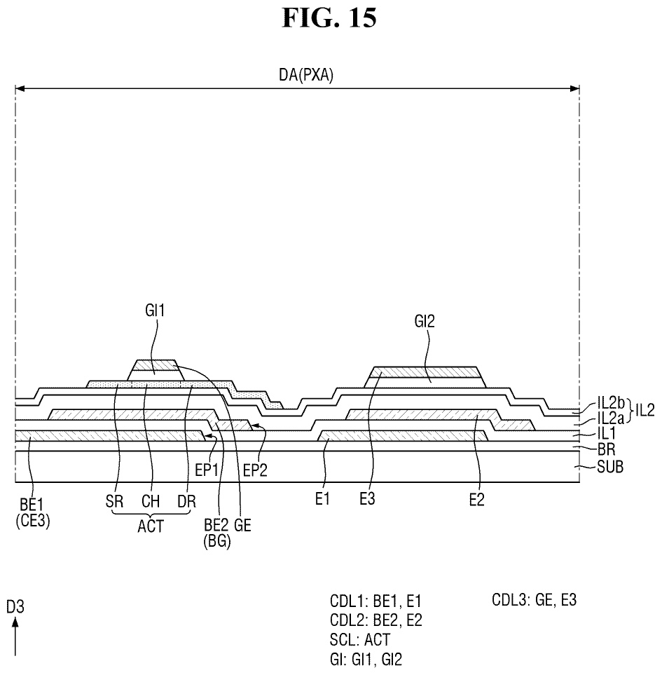

Thereafter, as illustrated in FIG. 15, the gate insulating layer GI and the third conductive layer CDL3 may be formed on the second insulating layer IL2. The gate insulating layer GI may include the first gate insulating layer GI1 and the second gate insulating layer GI2, and the third conductive layer CDL3 may include the gate electrode GE and the third electrode E3.

The gate insulating layer GI may be formed by a film forming process and a patterning process (e.g., an etching process using a mask) of an insulating film using at least one insulating material (e.g., an inorganic insulating material such as silicon oxide) exemplified above. The third conductive layer CDL3 may be formed through a film forming process (e.g., a deposition process) of forming a conductive film by using at least one conductive material mentioned above and a patterning process (e.g., an etching process using a mask) of patterning the conductive film.

In an embodiment, the third conductive layer CDL3 and the gate insulating layer GI may be etched sequentially or substantially simultaneously through an etching process using a mask. For example, the gate insulating layer GI may be etched by utilizing the mask used in the etching process of the third conductive layer CDL3 or by utilizing the third conductive layer CDL3 as a mask. Accordingly, the gate insulating layer GI may be patterned into a shape corresponding to the third conductive layer CDL3. For example, the patterns of the gate insulating layer GI may have a shape and/or size corresponding to the patterns of the third conductive layer CDL3.

The first gate insulating layer GI1 and the gate electrode GE may be formed on a part of the active layer ACT. The second gate insulating layer GI2 and the third electrode E3 may be formed on a portion of the second insulating layer IL2 in which the active layer ACT may not be disposed.

In the process of etching the gate insulating layer GI, the properties of the active layer ACT may be changed so that parts of the active layer ACT have different characteristics. Accordingly, the active layer ACT may be divided into multiple regions having different characteristics.

For example, at a portion that does not overlap the gate electrode GE and the first gate insulating layer GI1, oxygen vacancies may occur in the oxide semiconductor forming the active layer ACT due to an etching gas or the like. Accordingly, the active layer ACT may be divided into multiple regions (e.g., the channel region CH, the source region SR, and the drain region DR) having different characteristics. In an embodiment, oxygen vacancies may occur at a portion (e.g., the source region SR and the drain region DR) of the active layer ACT that does not overlap the gate electrode GE and the first gate insulating layer GI1, and may diffuse to a portion of the area overlapping the gate electrode GE and/or the first gate insulating layer GI1.

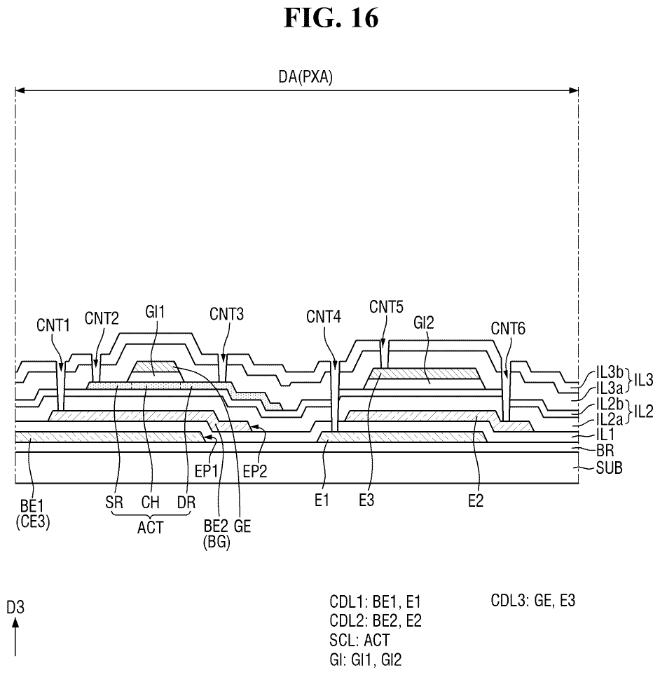

Thereafter, as illustrated in FIG. 16, the third insulating layer IL3 covering the semiconductor layer SCL, the gate insulating layer GI, and the third conductive layer CDL3 may be formed on the second insulating layer IL2. For example, the third insulating layer IL3 may be formed on the active layer ACT, the first and second gate insulating layers GI1 and GI2, the gate electrode GE, and the third electrode E3. The third insulating layer IL3 may be formed by a film forming process of an insulating film using at least one insulating material (e.g., an inorganic insulating material) exemplified above.

In an embodiment, the third insulating layer IL3 may be formed of at least a double layer including the first layer IL3a and the second layer IL3b. For example, the first layer IL3a including silicon oxide or silicon oxynitride and the second layer IL3b including silicon nitride may be sequentially formed on the second insulating layer IL2, the semiconductor layer SCL, the gate insulating layer GI, and the third conductive layer CDL3, so that the third insulating layer IL3 of a double layer may be formed.

Hydrogen may be introduced into the active layer ACT in the process of forming the third insulating layer IL3 and/or the heat treatment process before and after the process. Since hydrogen may be introduced into the active layer ACT, a part of the active layer ACT may become conductive (e.g., conductive to N type) at a portion containing a large number of oxygen vacancies. For example, the source region SR and the drain region DR may become conductive.

After film-forming the third insulating layer IL3, multiple contact holes may be formed in the third insulating layer IL3. For example, the first, second, third, fourth, fifth, and sixth contact holes CNT1, CNT2, CNT3, CNT4, CNT5, and CNT6 may be formed by an etching process using a mask. In an embodiment, the first, second, third, fourth, fifth, and sixth contact holes CNT1, CNT2, CNT3, CNT4, CNT5, and CNT6 may be formed substantially simultaneously by a single mask process, but the embodiments are not limited thereto.

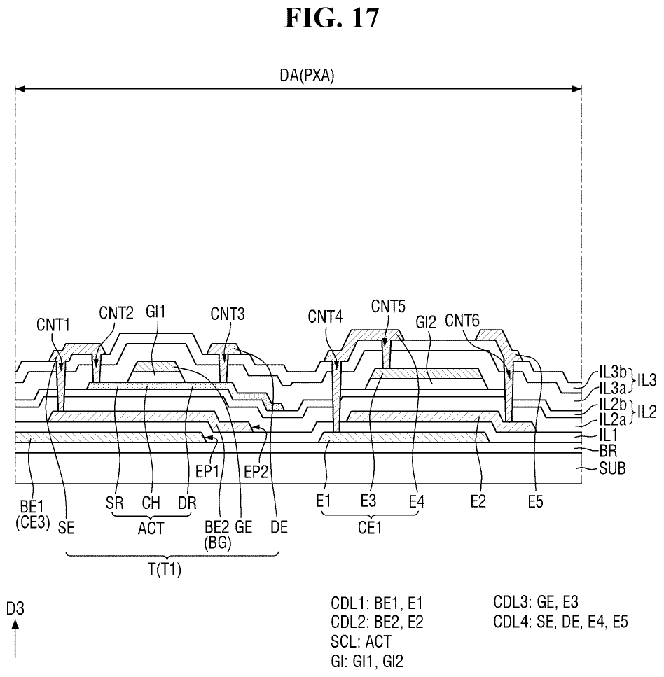

Thereafter, as illustrated in FIG. 17, the fourth conductive layer CDL4 may be formed on the third insulating layer IL3. The fourth conductive layer CDL4 may include the source electrode SE, the drain electrode DE, the fourth electrode E4, and the fifth electrode E5. In an embodiment, in case that at least one of the source region SR or the drain region DR replaces at least one of the source electrode SE or the drain electrode DE, at least one of the source electrode SE or the drain electrode DE may not be formed.

The patterns (e.g., the electrodes, the conductive patterns, and/or the wires provided in the fourth conductive layer CDL4) of the fourth conductive layer CDL4 including the source electrode SE, the drain electrode DE, the fourth electrode E4, and/or the fifth electrode E5 may be formed by a film forming process (e.g., a deposition process) of a conductive film using at least one conductive material exemplified above and a patterning process (e.g., an etching process using a mask) of the conductive film.

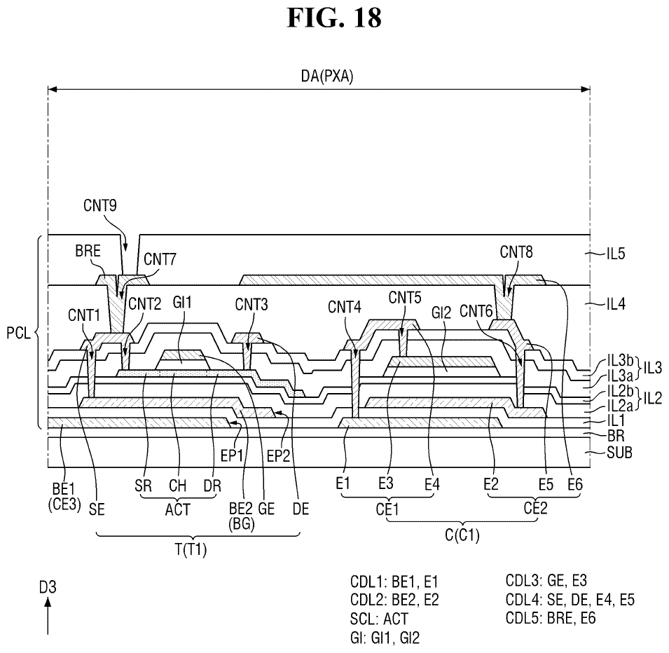

Referring to FIG. 18, the fourth insulating layer IL4, the fifth conductive layer CDL5, and the fifth insulating layer IL5 may be sequentially formed on the third insulating layer IL3. In case that manufacturing the display panel 110 that does not include the fifth conductive layer CDL5, the formation process of the fifth conductive layer CDL5 and the fifth insulating layer IL5 (or the fourth insulating layer IL4) may be omitted.

The fourth insulating layer IL4 may be formed on the third insulating layer IL3 by a film forming process of an insulating film by using at least one organic insulating material exemplified above. Multiple contact holes may be formed in the fourth insulating layer IL4. For example, the seventh contact hole CNT7 and the eighth contact hole CNT8 may be formed in the fourth insulating layer IL4.

The fifth conductive layer CDL5 may be formed on the fourth insulating layer IL4. The fifth conductive layer CDL5 may include the bridge electrode BRE and the sixth electrode E6. In an embodiment, in case that the second capacitor electrode CE2 does not include the sixth electrode E6, the sixth electrode E6 may not be formed.

The patterns (e.g., the electrodes, the conductive patterns, and/or at least one wire provided in the fifth conductive layer CDL5) of the fifth conductive layer CDL5 including the bridge electrode BRE and/or the sixth electrode E6 may be formed by a film forming process (e.g., a deposition process) of a conductive film using at least one conductive material exemplified above and a patterning process (e.g., an etching process using a mask) of the conductive film.

The fifth insulating layer IL5 may be formed on the fourth insulating layer IL4 and the fifth conductive layer CDL5. The fifth insulating layer IL5 may be formed by a film forming process of an insulating film using at least one organic insulating material exemplified above. The ninth contact hole CNT9 exposing the bridge electrode BRE (or the source electrode SE) may be formed in the fifth insulating layer IL5.

Through the above-described processes, the panel circuit layer PCL of the display panel 110 may be formed. As in the embodiments of FIGS. 4 and 7, in case that the display panel 110 includes the light emitting element layer LEL and the encapsulation layer ENL, the light emitting element layer LEL and the encapsulation layer ENL may be sequentially formed on the panel circuit layer PCL. Through the above-described processes, the display panel 110 and the display device 100 including the same according to the embodiments may be manufactured.

As described above, according to the display device 100 and the method for manufacturing the same according to the embodiments, the first end EP1 of the first bottom electrode BE1 and the second end EP2 of the second bottom electrode BE2 disposed below the active layer ACT may not overlap each other in the thickness direction of the substrate SUB. For example, the first end EP1 of the first bottom electrode BE1 and the second end EP2 of the second bottom electrode BE2 may be spaced apart from each other by a distance of at least about 0.6 μm in a plan view.

According to the embodiments, a void or seam that may occur around the first bottom electrode BE1, the second bottom electrode BE2, or the like may be alleviated or reduced, and it may be possible to increase the path (e.g., the movement distance of hydrogen) through which hydrogen may be introduced into the active layer ACT from the first bottom electrode BE1, the second bottom electrode BE2, or the like. Accordingly, hydrogen diffusion into the active layer ACT may be prevented or reduced, and the operating characteristics of the transistor T may be improved or stabilized. As a result, the operating characteristics of the transistor T and the pixel PX including the transistor T may be improved, and the image quality of the display device 100 may be improved.

In some embodiments, the first bottom electrode BE1 and the second bottom electrode BE2 may include the first metal layers ML1a and ML1b containing aluminum (Al) and may include the second metal layers ML2a and ML2b containing titanium (Ti) and covering the top surfaces of the first metal layers ML1a and ML1b, respectively. In an embodiment, the first bottom electrode BE1 and the second bottom electrode BE2 may further include the third metal layers ML3a and ML3b containing titanium (Ti) and covering the bottom surfaces of the first metal layers ML1a and ML1b, respectively. As an example, each of the first bottom electrode BE1 and the second bottom electrode BE2 may be formed of a triple layer of aluminum (Al)/titanium (Ti)/aluminum (Al).

According to the embodiments, the top surfaces and/or the bottom surfaces of the first metal layers ML1a and ML1b of the first bottom electrode BE1 and the second bottom electrode BE2 may be capped by the second metal layers ML2a and ML2b and/or the third metal layers ML3a and ML3b, respectively, so that a void or seam may be suppressed from occurring around the first bottom electrode BE1, the second bottom electrode BE2, or the like, and it may be possible to block hydrogen from diffusing in the third direction D3 or the like. Accordingly, it may be possible to more effectively prevent or reduce hydrogen from being introduced into the active layer ACT.

In some embodiments, the second insulating layer IL2 disposed between the second bottom electrode BE2 and the active layer ACT may include the first layer IL2a including silicon nitride and the second layer IL2b including silicon oxide or silicon oxynitride.

According to the embodiments, the insulating properties of the second insulating layer IL2 may be improved, and it may be possible to block hydrogen from diffusing from the lower portion of the second insulating layer IL2 into the upper portion of the second insulating layer IL2. Accordingly, it may be possible to more effectively prevent or reduce hydrogen from being introduced into the active layer ACT.

In concluding the detailed description, those skilled in the art will appreciate that many variations and modifications can be made to the embodiments without substantially departing from the principles of the disclosure. Therefore, the disclosed embodiments of the disclosure are used in a generic and descriptive sense only and not for purposes of limitation.

What is claimed is:

1. A display device comprising:
a substrate;
a first bottom electrode disposed on the substrate and having a first end;
a first insulating layer disposed on the first bottom electrode;
a second bottom electrode disposed on the first insulating layer, the second bottom electrode overlapping the first bottom electrode in a plan view;
a second insulating layer disposed on the second bottom electrode; and
a transistor comprising an active layer disposed on the second insulating layer, the transistor comprising a gate electrode overlapping the active layer in a plan view, wherein
the second bottom electrode overlaps the active layer in a plan view and has a second end adjacent to the first end, and
the first end and the second end do not overlap in a plan view.

2. The display device of claim 1, wherein the first end and the second end are spaced apart from each other by a distance of at least about 0.6 μm in a plan view.

3. The display device of claim 1, wherein
a part of the second bottom electrode overlaps the first end, and
the second end extends from the part of the second bottom electrode to an outside of the first end.

4. The display device of claim 1, wherein
a part of the first bottom electrode overlaps the second end, and
the first end extends from the part of the first bottom electrode to an outside of the second end.

5. The display device of claim 1, wherein
the first bottom electrode comprises a first metal layer containing aluminum (Al) and a second metal layer disposed on the first metal layer, and
the second metal layer contains titanium (Ti).

6. The display device of claim 5, wherein
the first bottom electrode further comprises a third metal layer disposed below the first metal layer, and
the third metal layer contains titanium (Ti).

7. The display device of claim 6, wherein the second metal layer and the third metal layer completely cover a top surface and a bottom surface respectively of the first metal layer.

8. The display device of claim 1, wherein
the second bottom electrode comprises a first metal layer containing aluminum (Al) and a second metal layer disposed on the first metal layer, and
the second metal layer contains titanium (Ti).

9. The display device of claim 8, wherein
the second bottom electrode further comprises a third metal layer disposed below the first metal layer, and
the third metal layer contains titanium (Ti).

10. The display device of claim 9, wherein the second metal layer and the third metal layer completely cover a top surface and a bottom surface respectively of the first metal layer.

11. The display device of claim 1, wherein
the second insulating layer comprises a first layer containing silicon nitride and a second layer disposed on the first layer, and
the second layer contains silicon oxide or silicon oxynitride.

12. The display device of claim 11, wherein a thickness of the first layer is greater than a thickness of the second layer.

13. The display device of claim 11, wherein the first layer has a thickness in a range of about 1000 Å to about 2000 Å.

14. The display device of claim 1, wherein the active layer contains an oxide semiconductor.

15. The display device of claim 14, further comprising:
a gate insulating layer disposed between the active layer and the gate electrode, the gate insulating layer covering a portion of the active layer, including a portion overlapping the gate electrode, and exposing another portion of the active layer.

16. The display device of claim 1, wherein
the transistor further comprises a source electrode disposed on a third insulating layer,
the third insulating layer is disposed on the gate electrode, and
the second bottom electrode is electrically connected to the source electrode.

17. The display device of claim 16, wherein the third insulating layer comprises a first layer containing silicon oxide or silicon oxynitride and a second layer disposed on the first layer, and the second layer contains silicon nitride.

18. The display device of claim 1, further comprising:
a light emitting element electrically connected to the transistor.

19. A method for manufacturing a display device, comprising:
forming a first bottom electrode on a substrate, the first bottom electrode having a first end;
forming a first insulating layer on the first bottom electrode;
forming a second bottom electrode on the first insulating layer, the second bottom electrode overlapping the first bottom electrode in a plan view, and the second bottom electrode having a second end adjacent to the first end;
forming a second insulating layer on the second bottom electrode; and
forming a transistor on the second insulating layer, the transistor comprising an active layer that overlaps the second bottom electrode in a plan view,
wherein the first end and the second end do not overlap in a plan view.

20. The method of claim 19, wherein the first end and the second end are spaced apart from each other by a distance of at least about 0.6 μm in a plan view.
